(19) United States
(12) Patent Application Publication
(10) Pub. No.: US 2025/0188609 A1
(43) Pub. Date: Jun. 12, 2025

(54) SEAM-FREE AND CRACK-FREE DEPOSITION

(71) Applicant: Lam Research Corporation, Fremont, CA (US)

(72) Inventors: Awnish Gupta, Hillsboro, OR (US); Jason Alexander Varnell, Tigard, OR (US); Bart J. van Schravendijk, Palo Alto, CA (US); Douglas Walter Agnew, Portland, OR (US); Praneeth Ramasagaram, Boise, ID (US)

(21) Appl. No.: 18/847,173

(22) PCT Filed: Mar. 15, 2023
(86) PCT No.: PCT/US2023/064472

§ 371 Date: Sep. 13, 2024

Related U.S. Application Data
(60) Provisional application No. 63/374,347, filed on Sep. 1, 2022.
(60) Provisional application No. 63/269,599, filed on Mar. 18, 2022.

(51) Int. Cl. C23C 16/455; C23C 16/52; C23C 16/56

(52) U.S. Cl. CPC C23C 16/45536; C23C 16/45544; C23C 16/52; C23C 16/56

(57) ABSTRACT

Methods and apparatuses for depositing material into features on a substrate by depositing a first portion of a material; etching a V-shaped hole at or near a feature opening; and depositing a second portion of the material to fill the feature are provided herein.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor processing may involve deposition of material into features. As features shrink and dimensions are narrowed, it is challenging to deposit material into the features. Some techniques for depositing material into small features results in the formation of a seam in the middle of a feature, which can cause cracking or other defects that can cause device failure.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method for processing substrates, the method including: providing a substrate having a feature having a feature opening to a process chamber; conformally depositing a first portion of a material into the feature; stopping depositing into the feature before a seam forms in the feature; after partially depositing the first portion of the material, exposing the substrate to an etching species to etch an angular opening, such as V-shaped hole, at or near the feature opening to form an etched surface; and depositing a second portion of the material onto the etched surface to fill the feature.

In various embodiments, at least one of the first portion and the second portion of the material is deposited using plasma-enhanced atomic layer deposition.

In some embodiments, the plasma-enhanced atomic layer deposition includes exposing the first portion of the material to a deposition precursor to form an adsorbed layer of the deposition precursor and exposing the adsorbed layer of the deposition precursor to a plasma in temporally separated pulses. For example, in some embodiments, the plasma is generated using a high frequency plasma. In some embodiments, the high frequency plasma is generated at a power of about 4500 W to about 6000 W. In some embodiments, the plasma is generated using a low frequency plasma. In some embodiments, the low frequency plasma is generated at a power of up to about 5000 W. In some embodiments, the plasma is generated by igniting oxygen gas. In some embodiments, the plasma is generated by igniting the oxygen gas in an environment including nitrous oxide and optionally argon.

In some embodiments, the plasma-enhanced chemical vapor deposition includes igniting a dual frequency plasma. In some embodiments, the dual frequency plasma is generated using a high frequency plasma power of about 3000 W to about 6000 W and a low frequency plasma power of about 1000 W to about 5000 W. In some embodiments, the dual frequency plasma is generated by igniting oxygen gas. In some embodiments, the igniting the oxygen gas is performed in an environment including one or more inert gases such as one \of nitrogen, argon, hydrogen, and combinations thereof.

In some embodiments, during the plasma-enhanced chemical vapor deposition, chamber pressure is about 600 mTorr to about 5000 mTorr.

In various embodiments, the second portion of the material is deposited using plasma-enhanced chemical vapor deposition.

In various embodiments, the second portion of the material is deposited using thermal chemical vapor deposition.

In some embodiments, after thermal chemical vapor deposition, a post-treatment process may be performed. In some embodiments, the post-treatment is performed in an environment oxygen-free environment. In some embodiments, the post-treatment includes exposing the substrate to a plasma. In some embodiments, the plasma is generated by igniting a gas such as one of nitrogen, argon, hydrogen, and combinations thereof. In some embodiments, the plasma is generated using dual frequency plasma having high frequency and low frequency. In some embodiments, high frequency plasma is generated at a power of up to about 6000 W and low frequency plasma is generated at a power of up to about 4000 W.

In various embodiments, the process chamber is a single-wafer process chamber.

In various embodiments, the conformally depositing of the first portion and the exposing the substrate to the etching species is performed without breaking vacuum.

In various embodiments, the etching species is oxygen-free.

In various embodiments, the angular opening, or in some embodiments, V-shaped hole, is etched to a depth of about 10% to about 50% of the depth of the feature. In various embodiments, the V-shaped hole is etched to a depth of less than about 10% of the depth of the feature.

Another aspect involves an apparatus for processing substrates, the apparatus including: one or more process chambers, each process chamber including a chuck; one or more gas inlets into the process chambers and associated flow-control hardware; and a controller having at least one processor and a memory, whereby the at least one processor and the memory are communicatively connected with one another, the at least one processor is at least operatively connected with the flow-control hardware, and the memory stores computer-executable instructions for controlling the at least one processor to at least control the flow-control hardware to: cause introduction of a first deposition precursor and a first reactant in temporally separated pulses to partially fill a feature on a substrate with a first portion of material; cause introduction of an etching gas to etch the first portion of the material to form an angular opening, or in some embodiments, a V-shaped hole, at or near a feature opening of the feature; and cause introduction of a second deposition precursor and a second reactant and optional generation of a plasma to form a second portion of the material to fill the feature.

These and other aspects are described further below with reference to the drawings.

### BRIEF DESCRIPTION OF THE DRAWINGS

FIG. 1 shows features undergoing semiconductor processing involving deposition of a material into a feature.

FIGS. 2A, 2B, 2C, and 2D show process flow diagrams of operations that may be performed in accordance with certain disclosed embodiments.

FIG. 3 shows features undergoing semiconductor processing involving deposition of a material into a feature in accordance with certain disclosed embodiments.

FIG. 4 is a schematic illustration of a chamber that may be used in accordance with certain disclosed embodiments.

FIG. 5 is a schematic illustration of a tool that may be used in accordance with certain disclosed embodiments.

FIG. 6 is a schematic illustration of a tool that may be used in accordance with certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor manufacturing processes may involve deposition of various materials into small features. For example, in some processes, silicon-containing materials may be deposited into features. Example silicon-containing materials include but are not limited to silicon oxide, silicon nitride, silicon carbide, and doped variants thereof.

As devices shrink, features become increasingly narrow, resulting in smaller feature openings and sidewalls of the features that are positioned closer together. It can be challenging to deposit materials into such small features. One technique for depositing material into features is atomic layer deposition (ALD).

ALD is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of precursor from the chamber, (iii) delivery of a second reactant and optionally ignite plasma, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In ALD deposition of silicon oxide films, this reaction involves reacting oxygen plasma with carbon and nitrogen to form a gaseous species; oxidizing silicon to silicon oxide; eliminating trace carbon, nitrogen, and hydrogen impurities; and increasing bonding and densification of the film.

Unlike a chemical vapor deposition (CVD) technique, ALD processes use surface-mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas, is introduced to the chamber so that some of these molecules react with the first precursor adsorbed on the surface. In some processes, the second precursor reacts immediately with the adsorbed first precursor. In other embodiments, the second reactant reacts only after a source of activation is applied temporally. The chamber may then be evacuated again to remove unbound second reactant molecules. As described above, in some embodiments the chamber may not be completely evacuated. Additional ALD cycles may be used to build film thickness.

In some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

ALD processes form conformal films in such features, which involves growth of the film on sidewalls and the bottom of the feature. As the film grows from each sidewall, when the material from each sidewall come in contact in the middle of a feature, sometimes a seam can form in the middle of the feature. The seam may not have the same structural integrity as the rest of the material in the feature that was previously grown, but additional material also may not be easily deposited into the seam to improve the structural integrity in the middle of the feature. For example, silicon-containing deposition precursors may not fit in the seam. The material at the seam may not be chemically bonded so the structural integrity of the material at the seam is weaker than the rest of the feature. While some techniques involve annealing the substrate after filling the features to reduce or eliminate the seam, heating may also cause cracking especially starting at the seam, thereby causing a hole to form in the middle of the feature where the seam once was. This may be due to the structure next to the crack then having reduced structural integrity, causing periodicity or additional film cracking. In wet etch rate testing, the material at or near the seam etches faster than the material at the side wall. When the device undergoes higher temperature processing even without an annealing operation, the seam may open, or crack, or both, possibly due to shrinking because the film prior to annealing may have had lower quality. Once a crack is formed in one feature, features close to that feature may be relaxed, resulting in an observed cracking frequency that depends on the original film quality and the temperature in which the film was annealed. Additionally, cracking may also cause bowing of feature structures, thereby affecting the structural integrity of films formed in subsequent operations on the substrate.

As an alternative to ALD, high temperature chemical vapor deposition (CVD), such as but not limited to TEOS-based CVD, may be used as deposited films may have lower shrinkage and are less susceptible to opening or cracking. However, it is challenging to deposit materials using this technique in features having an aspect ratio greater than about 4:1. Still another alternative is using high density plasma to deposit the film. However, using high density plasma might involve additional operations, including deposition, etching performed in a separate chamber or station, further deposition, and repeated operations thereof to fill the features. This may reduce throughput due to the slower process. Yet another alternative is to anneal in a controlled high temperature in a nitrogen-containing gas-based environment (such as an environment having nitrogen gas), such that the gas environment is utilized to improve or reduce the seam. However, sometimes even in such embodiments, the seam may shrink or crack.

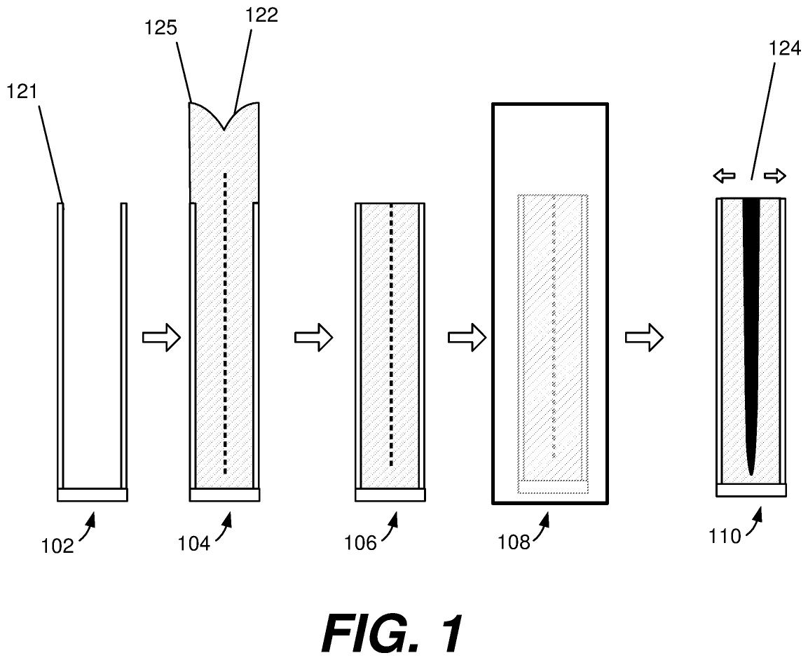

FIG. 1 shows an example of a feature in a substrate undergoing various processing operations. Feature 102 has a liner layer with sidewalls 121. Feature 104 shows dielectric material 125 deposited conformally into feature 104 whereby a seam 122 is then subsequently formed due to the sidewall growth on each side of the feature merging in the center of the feature 104. Feature 106 shows that overburden may be removed by planarization to result in a horizontal surface such that the filled dielectric material is flush with the feature opening. Feature 108 undergoes an anneal process. Feature 110 shows that after annealing, the seam 122 cracks forming a hole 124 in the center of the feature as the dielectric material that is deposited densifies and shrinks towards the sidewalls.

Provided herein are methods and apparatus for forming seam-free and crack-free films in features. Such techniques may be utilized with a variety of films. In various embodiments, certain disclosed embodiments can be used for any film deposited by ALD. Methods and apparatuses herein involve etching an angular opening, such as a V-shaped opening, at or near the feature opening to form a hole, and filling the hole with a dense, seam-free film using one of various deposition techniques.

Certain methods involve silicon oxide deposition which does not crack upon further high temperature processes after structure gapfill. Due to feature sizes shrinking and some feature dimensions narrowing, many applications have shifted to ALD deposition. ALD deposition sometimes results in formation of a seam since it deposits conformally and film growth is from the sidewalls as shown in FIG. 1. This seam becomes a weak spot in the film and during integration schemes, when the device undergoes higher temperature processing, the weak seam may open up and crack as described above.

Certain disclosed embodiments herein involve etching an angular opening, such as a V-shaped opening, and filling it with a dense film prior to closing of the seam such that a seam-free film can be formed. This reduces cracking in the structure during subsequent higher temperature operations.

Certain disclosed embodiments can be performed to form seam-free deposition on large area structures, such as for staircase fill, and filling of slits. Certain disclosed embodiments may also be used for other structures where seam-free and/or crack-free deposition at or near feature openings or surfaces of materials on a substrate may be used. Example deposition techniques that may be used to fill the hole include but are not limited to ALD, plasma-enhanced CVD (PECVD), and thermal CVD with post-treatment.

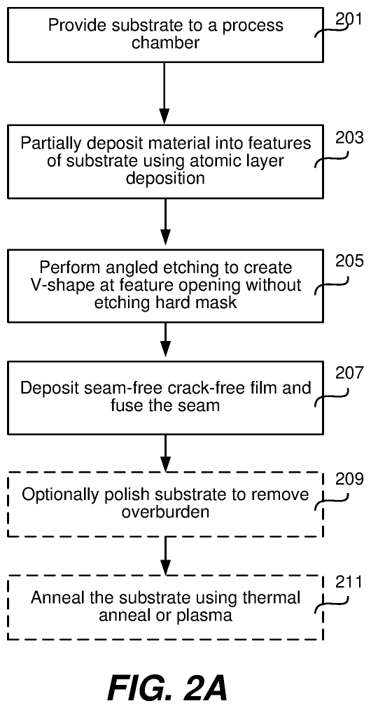

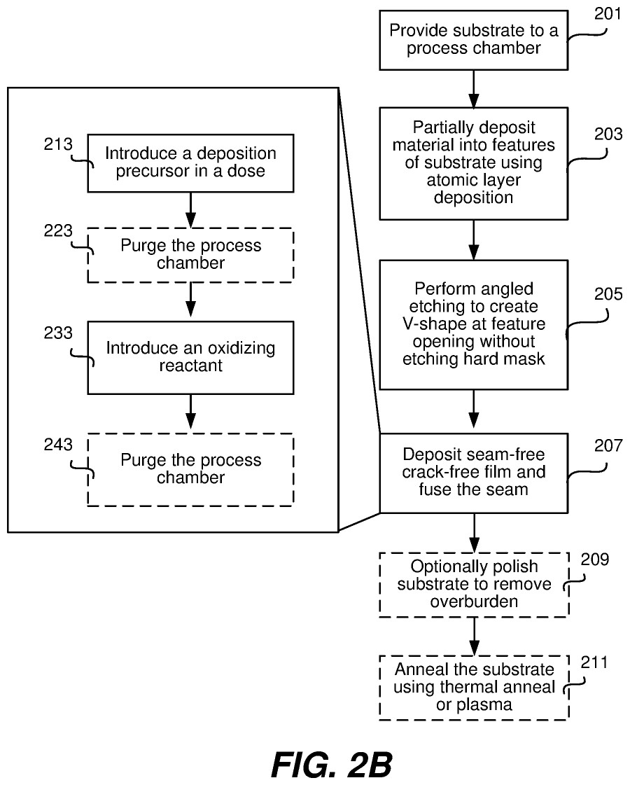

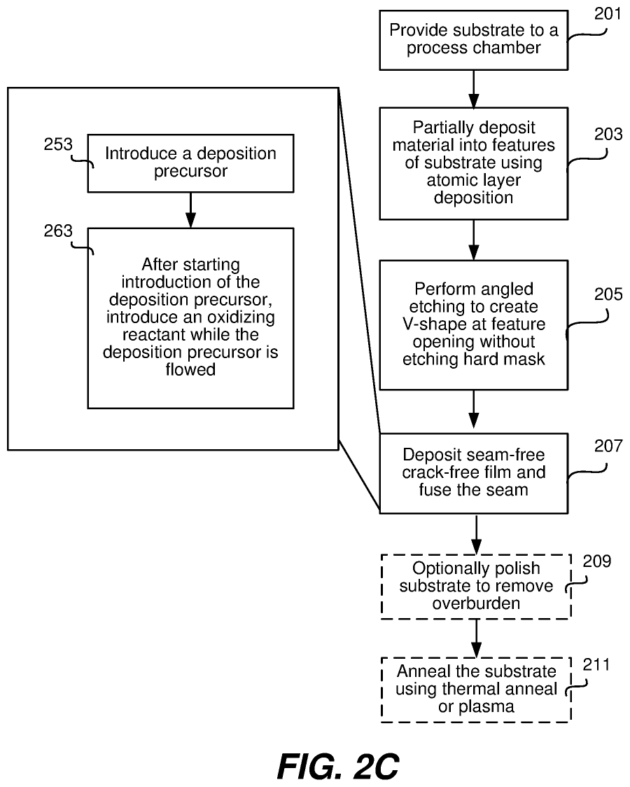

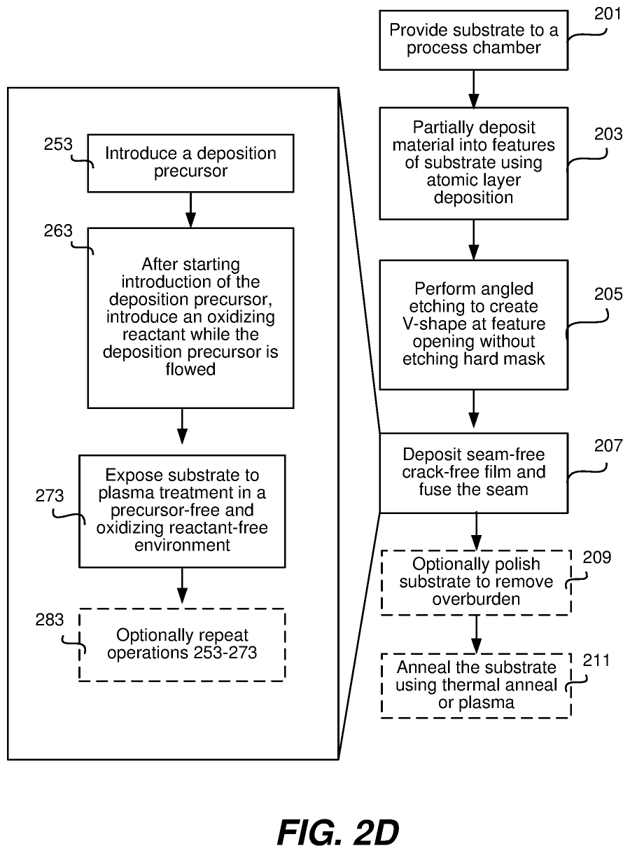

FIG. 2A provides a process flow diagram depicting operations that may be performed in accordance with certain disclosed embodiments. Operation 201 involves providing a substrate to a process chamber.

The substrate may be a silicon wafer, e.g., a 200-mm wafer, a 300-mm wafer, or a 450-mm wafer, including wafers having one or more layers of material, such as dielectric, conducting, or semi-conducting material deposited thereon. In various embodiments, the substrate is patterned. A patterned substrate may have “features” such as pillars, poles, trenches, via or contact holes, which may be characterized by one or more of narrow and/or re-entrant openings, constrictions within the feature, and high aspect ratios. The feature(s) may be formed in one or more of the above described layers. One example of a feature is a pillar or pole in a semiconductor substrate or a layer on the substrate. Another example is a trench in a substrate or layer. The substrate may include a hard mask layer over features where the hard mask is used as a mask to prevent deposition on certain regions of the substrate surface.

In some embodiments, the feature(s) such as a pillar may have an aspect ratio of at least about 1:1, at least about 2:1, at least about 4:1, at least about 6:1, at least about 10:1, at least about 100:1, or at least about 200:1 or higher. The feature(s) may also have a dimension near the opening, e.g., an opening diameter or line width of between about 10 nm to 500 nm, for example between about 25 nm and about 300 nm. Certain disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature.

In an operation 203, a material is partially deposited into features of a substrate using a deposition technique. The material may be a dielectric material. The material may be silicon-containing material. The silicon-containing material may be silicon oxide. The deposition technique may be ALD, PECVD, or thermal CVD with post-treatment.

One example of a method of depositing material partially into the features involves ALD.

For deposition of silicon oxide, the substrate may be exposed to a silicon-containing precursor for a duration sufficient to adsorb the silicon-containing precursor onto a surface of the substrate. The substrate may be exposed to a silicon-containing precursor by introducing a silicon-containing precursor to a process chamber housing the substrate. The silicon-containing precursor may be any silicon-containing precursor, such as a halosilane, or any silicon-containing precursor described elsewhere herein, such as in the Definitions and Precursors section. Flow of the silicon-containing precursor may be stopped and the process chamber may be optionally purged to remove excess silicon-containing precursor from a processing space in the process chamber. A reactant such as an oxygen-containing gas or plasma may be introduced after purging. In some embodiments, the substrate having the silicon-containing precursor adsorbed thereon is exposed to a reactant such as an oxygen-containing gas or plasma, which converts the silicon-containing precursor to silicon oxide, thereby forming silicon oxide on a surface of the substrate. The oxygen-containing gas or plasma flow may be stopped and the process chamber may optionally be purged yet again. Various cycles of exposure to silicon-containing precursor and oxygen-containing gas or plasma may be used in temporally separated pulses until sufficient thickness of silicon oxide is formed. For operation 203, silicon oxide may be formed until most but not all of the feature is filled with silicon oxide, and until at least some of the silicon oxide grown from two sidewalls of a feature being filled with silicon oxide are in contact with one another.

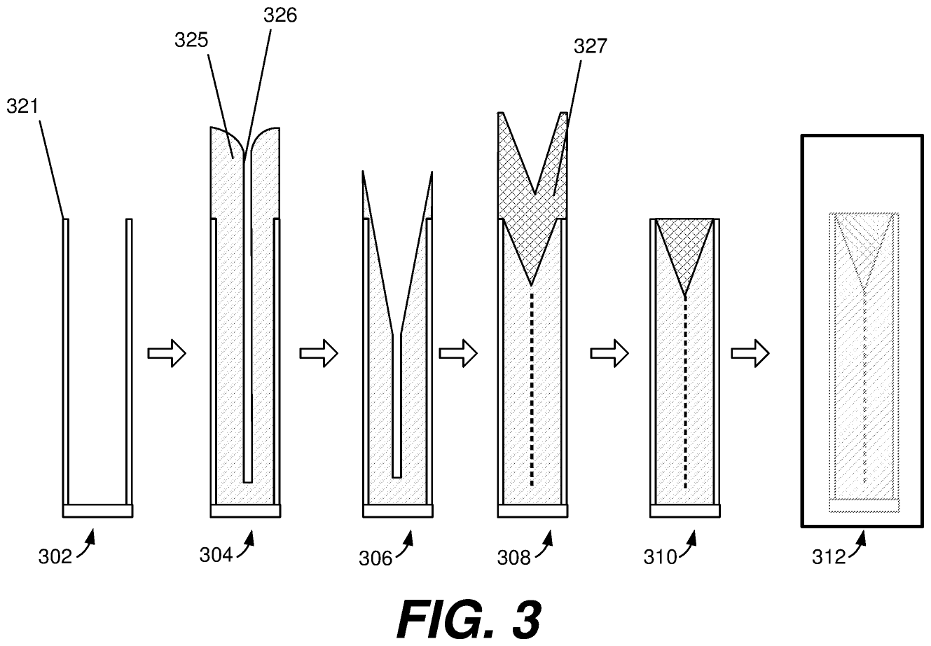

In an operation 205, etching may be performed to create an angular shape, such as a V-shape, at the feature opening without etching a hardmask. The term “angular shape” refers to the shape of the feature after etching from a cross-sectional point of view, such as later shown in FIG. 3 and further described below. The “angular” aspect refers to the sidewalls being sloped at an angle. A “V-shape” means the angular shape from a side profile looks like a letter V, with sidewalls sloping outwards from the center of the feature to a widened feature opening as the sidewall approaches the surface level of the layer of material. Etching in operation 205 causes exposed surfaces of the material deposited in operation 203 to be sloped, such that material on sidewalls are sloped downwards towards the center of the feature, or sloped downwards towards the gap between the two sidewalls. The angle of the slope may affect the overall deposition process, and may be modulated by tailoring process conditions. For example, in some embodiments, the angle may be at or about 45° on either sidewall. In some embodiments, the angle may be about 45° to about 60°. The angle may be determined by projecting the slope of each sidewall to a center point in the center of the feature as determined from a cross-section side view of the feature. That is, an angle having higher value means a wider opening with less steep slopes, and an angle having a lower value means a narrower opening with steeper slopes. The steeper the tangle, the greater the depth of material deposited will be seam free. In some embodiments, for high aspect ratio features or features having narrow openings, the angle may be less steep so as not to risk forming a seam in subsequent deposition. In some embodiments, the angle be greater than 45° so as not to form cracks in the deposited material. In some embodiments, the depth of the angular etching (e.g., the depth to which the sidewalls are sloped) may be tailored to be of sufficient depth to achieve seam-free deposition but also to avoid being too deep so as to cause cracking. This may be referred to as a “crack stop.” In some embodiments, the crack stop is about 10% to about 50% of the depth of a feature.

In various embodiments, a V-shaped point (e.g., the point at which a projection of the sloped sidewalls would meet at or near a center of a feature) is formed at a depth lower than a top planar region of the substrate so that in planarization or other subsequent processing operations, the seam is not exposed or opened.

During operation 205, the substrate is exposed to various process conditions to achieve angled etching. One or more etching gases may be used. A plasma is ignited to generate plasma species which react with the deposited material on the substrate surface. The etching is performed using ions and radicals, and in some embodiments, sputtering. In some embodiments, the ions and radicals are generated using a high RF power. In some embodiments, the most sputtering occurs at 45° and hydrogen may be added to ignite the plasma to increase the steepness of the slope of the V-shaped etching. Etching may cause an angular or a V-shape because material at or near the seam may be more susceptible to etching.

In some embodiments, a bias may be used. Where bias is used, the power may be up to about 1000 V.

Example etching gases include halogen-containing gases, such as fluorine-containing gases. One example fluorine-containing gas is nitrogen trifluoride. One or more additive gases may also be used during etching, including but not limited to, argon, helium, oxygen, hydrogen, and combinations thereof.

The etching gas may be flowed at a flow rate of about 100 sccm to about 500 sccm for a single-wafer chamber. The one or more additive gases may be flowed at a flow rate of about 0 slm to about 13 slm. Argon may be flowed at a flow rate of about 8 slm to about 13 slm. Helium may be flowed at a flow rate of about 0 slm to about 5 slm. Oxygen may be flowed at a flow rate of about 0 slm to about 5 slm.

Process conditions of the plasma may vary depending on the gases used and the desired depth of the angular or V-shaped etching. In some embodiments, dual frequency plasma is used. High frequency (HF) radio frequency (RF) plasma may be generated at a power of about 500 W to about 3000 W. Low frequency (LF) RF plasma may be generated at a power of about 2000 W to about 4000 W. In some embodiments, slope of the angular or V-shaped etching may be decreased by decreasing HF power. In some embodiments, slope of the angular or V-shaped etching may be decreased by increasing LF power. For example, etching using about 2000 W HF and 3000 W LF may form angular or V-shaped etching having slopes of the sidewall at or near the feature opening of about 60°, while etching using 500 W HF and 3000 W HF may form V-shaped etching having slopes of the sidewall at or near the feature opening of about 55°. In some embodiments, a higher RF power may increase density of the film deposited in operation 203. In some embodiments, a higher density film may not necessarily be desired. In some embodiments, a seam-free film may be deposited in operation 203 using CVD which may not necessarily change the density of the film.

Etching may be performed for a duration of about 1 second to about 3000 seconds, or about 1 second to about 2500 seconds, or about 1 second to about 2000 seconds, or about 1 second to about 1000 seconds, or about 1 second to about 500 seconds, or about 10 seconds to 100 seconds or about 60 seconds In some embodiments, increasing etch duration may increase the slope of the angular or V-shaped etching.

During operation 205, the process chamber housing the substrate may be set to a pressure of about 0.5 Torr to about 2 Torr.

Returning to FIG. 2A, in an operation 207, a seam-free crack-free film is deposited and the seam may be fused. The film deposited is the same material as the material deposited in operation 203. The film may be deposited using ALD, PECVD, or thermal CVD with post-treatment. Deposition is performed to fill the feature at the angular or V-shaped opening and thereby fill any seam with higher quality material, such as higher quality silicon oxide. Higher quality may refer to one or more properties, such as stress, density, k-value, wet etch rate, and others.

In various embodiments, deposition subsequent to etching an angular or V-shaped opening at or near the feature opening is seam-free because the feature after etching the angular or V-shaped has a lower aspect ratio and it may be easier for the deposition process gases and/or plasma species to reach deeper regions of the feature, such as at the bottom of the feature. For example, ALD processes and PECVD processes can deposit seam-free material in this way. Additionally, any redeposition of sputtered material results in a seam-less deposition due to the lower aspect ratio; in contrast, where an angular or V-shape is not etched at or near a feature opening in certain high aspect ratio features, voids may form in the middle of a feature due to redeposition of sputter material at or near the feature opening.

In another example, CVD may be used to deposit material into the feature after etching an angular or V-shape. In various embodiments, certain disclosed embodiments may deposit seam-free materials without performing a post-treatment or an anneal after depositing the material. That is, by forming an angular or V-shape opening prior to filling the feature, the deposited material is seam-free without having to anneal or treat the substrate after filling the feature.

FIG. 2B provides an example of depositing the film using ALD.

In operation 213, a deposition precursor is introduced in a dose. In some embodiments, the deposition precursor is a silicon-containing precursor. Silicon-containing precursors are further described below in the Definitions and Precursors section.

In various embodiments, the deposition precursor is flowed at a flow rate of about 0.1 slm to about 0.5 slm. During the dose, the pressure may be about 1 Torr to about 25 Torr. The deposition precursor is introduced without igniting a plasma. The deposition precursor is introduced in a plasma-free environment. The deposition precursor is introduced thermally. The substrate temperature during the dose is about 400° C. to about 700° C. or about 650° C. The dose may be performed for a duration of about 0.05 second to about 1 second.

In an operation 223, the process chamber is optionally purged. Purging the chamber may involve flowing a purge gas or a sweep gas, which may be a carrier gas used in other operations or may be a different gas. In some embodiments, purging may involve evacuating the chamber. Example purge gases include argon, nitrogen, hydrogen, and helium. In some embodiments, operation 223 may include one or more evacuation subphases for evacuating the process chamber. Alternatively, it will be appreciated that operation 223 may be omitted in some embodiments. Operation 223 may have any suitable duration, such as between about 0 seconds and about 60 seconds, for example about 0.01 seconds.

In an operation 233, an oxidizing reactant is introduced. This may be referred to as “conversion” whereby the oxidizing reactant converts deposition precursor to the material. The oxidizing reactant may be one or more oxygen-containing gases and/or oxygen-containing plasma. Oxygen-containing plasma may be generated by igniting an oxygen-containing gas. Oxygen-containing gases include but are not limited to oxygen, nitrous oxide, ozone, peroxides, carbon monoxide, carbon dioxide, and others. In one example, during operation 233, oxygen gas is flowed using a flow rate of about 1 slm to about 10 slm for a single-wafer chamber. Oxygen gas may be flowed with nitrous oxide having a flow rate of about 0 slm to about 10 slm for a single-wafer chamber. Oxygen gas may also be flowed with argon having a flow rate of about 3 slm to about 22 slm for a single-wafer chamber. Oxygen gas may be ignited using a plasma having HF RF power of about 4500 W to about 6000 W, and LF RF of about OW to about 5000 W for a single-wafer chamber. In some embodiments, only HF RF plasma is used. During operation 233, the chamber pressure may be about 2 Torr to about 6 Torr.

In an operation 243, the process chamber is optionally purged. Purging may be performed using process conditions and gases described above with respect to operation 223.

Operations 213 and 233, or 213, 223, 233, and 243 may be repeated in cycles to deposit film of variable thickness sufficient to deposit a seam-free, crack-free film while fusing the seam which may be due in part to use of high power plasma during deposition.

FIG. 2C shows another embodiment for depositing the seam-free crack-free film in operation 207 of FIG. 2A. In an operation 253, a deposition precursor is introduced. The deposition precursor may be a silicon-containing precursor such as any of those described above with respect to operations 203, 213, and elsewhere herein. Any suitable exposure time during operation 253 may be used. In some embodiments, exposure time during operation 253 may be about 0.05 second to about 1 second. The exposure time may be the time prior to introducing plasma and oxygen-containing gases. In various embodiments, the deposition precursor is flowed at a flow rate of about 0.1 slm to about 0.5 slm. During the dose, the pressure may be about 1 Torr to about 6 Torr. The deposition precursor is introduced without igniting a plasma. The deposition precursor is introduced in a plasma-free environment. The deposition precursor is introduced thermally. The substrate temperature during the dose is about 500° C. to about 700° C. or about 650° C.

In operation 263, after starting introduction of the deposition precursor, an oxidizing reactant is introduced while the deposition precursor is flowed. In some embodiments, this may be referred to as CVD. In some embodiments, the oxidizing reactant is a plasma. In such embodiments, the process may be referred to as PECVD. The oxidizing reactant may be any of those described above with respect to operation 233. In some embodiments, the oxidizing reactant includes one or more oxidizing gases, and optionally one or more inert gases. In some embodiments, a mixture of oxygen gas and argon gas is introduced. In some embodiments, a mixture of oxygen gas, argon gas, and hydrogen gas is introduced. In some embodiments, a mixture of oxygen gas, argon gas, and nitrogen gas is introduced. In some embodiments, a mixture of oxygen gas, argon gas, hydrogen gas, and nitrogen gas is introduced.

In some embodiments, oxygen gas is flowed at a flow rate of about 1 slm to about 5 slm. In some embodiments, argon gas is flowed at a flow rate of about 4.5 slm to about 22 slm. In some embodiments, hydrogen is flowed at a flow rate of about 0 slm to about 5 slm.

The oxidizing reactant is ignited in a plasma generated using dual frequency plasma. In some embodiments, the HF RF power is about 3 kW to about 6 kW for a single-wafer chamber. In some embodiments, the LF RF power is about 1 kW to about 5 kW for a single-wafer chamber.

During operation 263, the chamber may be set at a pressure of about 600 mTorr to about 5000 mTorr for a single-wafer chamber. The substrate temperature may be about 500° C. to about 700° C., or about 650° C. During dual frequency PECVD, the deposition precursor and oxidizing reactant are introduced such that they can react in a processing region above the substrate and form silicon oxide on the substrate. In various embodiments, this helps form a high quality silicon oxide film that is seam-free and crack-free over the feature now having an angular surface such as a V-shaped surface.

FIG. 2D shows an alternative deposition technique for performing operation 207. FIG. 2D involves an enhanced thermal CVD film, or a film deposited by thermal CVD followed by post-treatment. Treatment may be performed using a plasma to modify properties of the thermally deposited film and thereby form a high quality film.

In operation 253 of FIG. 2D, a deposition precursor is introduced. The deposition precursor may be a silicon-containing precursor. This operation may be the same as or may use any of the precursors and/or process conditions such as those described above with respect to operation 253 in FIG. 2C.

In operation 263, after starting introduction of the deposition precursor, an oxidizing reactant is introduced while the deposition precursor is flowed. In operation 263, after starting introduction of the deposition precursor, an oxidizing reactant is introduced while the deposition precursor is flowed. In some embodiments, this may be referred to as CVD. In some embodiments, the oxidizing reactant is a plasma. In such embodiments, the process may be referred to as PECVD. The oxidizing reactant may be any of those described above with respect to operation 233. This may be the same as or use the same chemistries and/or process conditions as operation 263 in FIG. 2C. In some embodiments, operation 263 is thermal, or plasma-free, or performed in a plasma-free environment.

In some embodiments, the process conditions may vary. For example, in some embodiments, any one or more of the following features may be used: oxygen gas is flowed at a flow rate of about 2 slm to about 10 slm; argon gas may be flowed at a flow rate of about 50 slm to about 70 slm; nitrogen gas may be flowed at a flow rate of about 15 slm to about 35 slm; and hydrogen gas may be flowed at a flow rate of about 500 sccm to about 5000 sccm.

The chamber pressure during operation 263 of FIG. 2D may be about 15 Torr to about 30 Torr. In this example in FIG. 2D, no plasma is ignited during introduction of the deposition precursor and/or the oxidizing reactant. For example, the deposition precursor and the oxidizing reactant are reacted thermally, or in a plasma-free environment, or without igniting a plasma.

After flow of the deposition precursor and/or the oxidizing reactant is stopped, in operation 273, the substrate is exposed to a plasma treatment in a precursor-free and oxidizing reactant-free environment. The plasma treatment may be performed by introducing a plasma into the chamber. In some embodiments, the process chamber is purged between stopping flow of the deposition precursor and/or the oxidizing reactant and introducing the plasma. In some embodiments, the plasma is generated in situ by flowing a treatment gas into the chamber and igniting the plasma. In some embodiments, the plasma is generated remotely by igniting a treatment gas in a remote plasma generator to generate plasma species, which are delivered to the process chamber housing the substrate.

In some embodiments, plasma treatment is performed by exposing the substrate to plasma species generated from an inert gas, such as argon, nitrogen, hydrogen, or helium. The plasma species may be generated from a treatment gas. The treatment gas used during operation 273 may be oxygen-free. In some embodiments, the treatment gas includes one or more of nitrogen, hydrogen, and argon. In some embodiments, the treatment gas includes argon, nitrogen, and hydrogen gas. The nitrogen gas may be flowed at a flow rate of about 15 slm to about 35 slm for a single-wafer chamber. Argon gas may be flowed at a flow rate of about 50 slm to about 70 slm for a single-wafer chamber. Hydrogen gas may be flowed at a flow rate of about 500 sccm to about 5000 sccm for a single-wafer chamber. In some embodiments, any one or more of argon, nitrogen, or hydrogen may be used as a dilution gas, carrier gas, or gas used to stabilize flow of other gases.

Operation 273 may be performed at a chamber pressure of about 15 Torr to about 30 Torr.

The plasma generated in operation 273 may be a dual frequency plasma. In some embodiments, the plasma is a single frequency plasma.

The power of an HF RF plasma may be about 0 W to about 6000 W. The power of an LF RF plasma may be about 0 W to about 4000 W. In one example, the HF power is about 2000 W and the LF power is about 500 W. In another example, the HF power is about 6000 W and the LF power is about 4000 W.

Plasma treatment may be used to densify or modify the film as deposited thermally in operations 253 and 263. In some cases, plasma treatment allows cross-linking to fuse seams and improve the integrity of the deposited film.

Operation 273 may be performed for a duration of about 0.5 second to about 5 seconds.

In operation 283, operations 253-273 are optionally repeated in cycles. For example, plasma is turned off prior to a repeated operation 253, then deposition precursor in operation 253 and oxidizing reactant in operation 263 are flowed for thermal deposition, then flows for deposition precursor and oxidizing reactant are turned off, and plasma is turned on again with one or more of argon, nitrogen, hydrogen gas to treat the film. Operations may be repeated until the film is of a desired thickness. Returning to FIG. 2A, in an operation 209, the substrate is optionally polished to remove any overburden deposited over the features. The substrate may be polished by chemical mechanical planarization or by any other etching or planarizing method.

In an operation 211, the substrate is optionally annealed using thermal anneal or plasma anneal. A thermal anneal may be performed at a temperature of about 700° C. to about 1000° C. In some embodiments, a thermal anneal is performed using an external furnace or using rapid thermal anneal. A plasma anneal may be used. The plasma may be a single frequency or dual frequency plasma.

In some embodiments, annealing changes properties of the deposited film by densifying, increasing cross-linking, hardening, modifying the stress of, or otherwise modifying other properties of the film. In some embodiments, after annealing the material may have a wet etch rate in 100:1 HF of less than about 25 Å/min.

FIG. 3 shows an example schematic illustration of a feature undergoing various embodiments in accordance with certain disclosed embodiments. Illustration 302 shows a feature with sidewalls 321. This feature may be present on a substrate such as one that is provided in operation 201 discussed above with respect to FIG. 2A. Illustration 304 shows the feature from illustration 302 is now partially filled with material 325 using a conformal deposition technique, such as ALD, but deposition is stopped before the material completely fills the feature, thereby leaving a gap 326 in the partially filled feature. Such deposition may be in accordance with operation 203 of FIG. 2A. Illustration 306 shows that an angular opening such as a V-shaped opening is etched such that material 325 now has exposed surfaces that are sloped, where the slopes are angled towards the gap in the middle of the feature. Illustration 308 shows additional material 327 deposited, thereby filling the gaps and fusing the seam, also forming some overburden over the feature walls. Such material may be deposited by any of the methods described above with respect to FIGS. 2B, 2C, and 2D, thereby forming higher quality film for the rest of the feature fill. Illustration 310 shows etching of the overburden to result in a horizontal surface aligned with the hard mask and the feature walls. Illustration 312 shows an annealing operation that may be used to further improve the quality of the film deposited in the feature, improve cross-linking, and fuse the seam resulting in good feature fill that while may still have some seam in the middle of a feature, has little or no seam at or near the feature opening, which prevents breakage, cracking, or weakened structural integrity when subject to other later process conditions.

### Apparatus

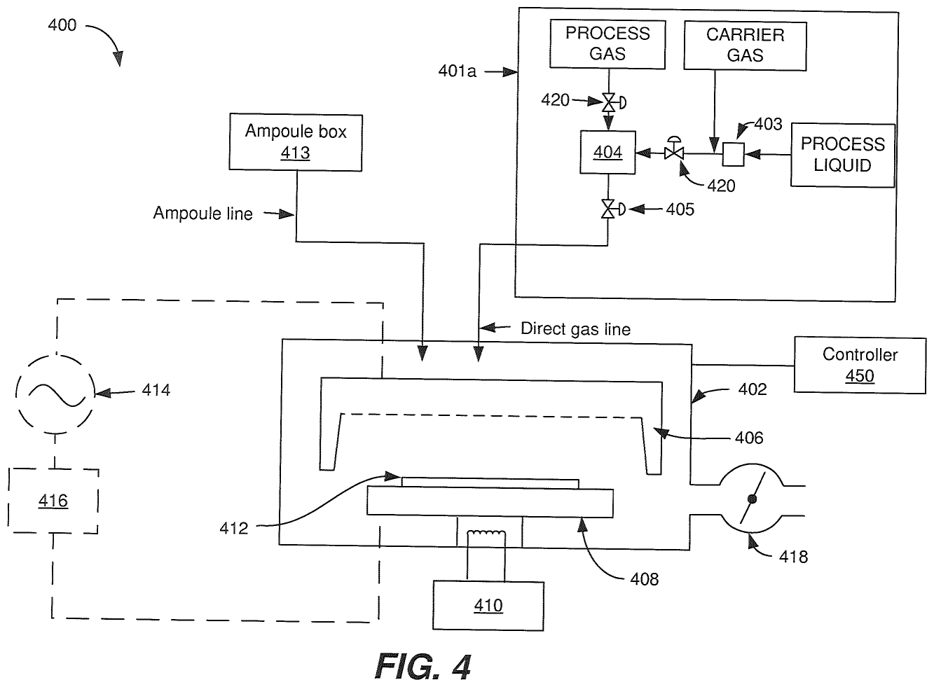

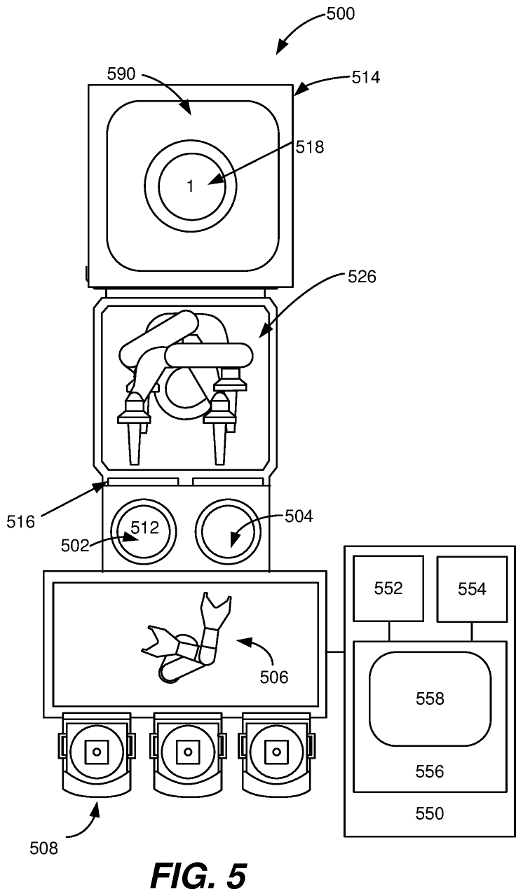

FIG. 4 depicts a schematic illustration of an embodiment of an atomic layer deposition (ALD) process station 400 having a process chamber body 402. In various embodiments, a single process station 400 is implemented in a tool such as shown in FIG. 5. In some embodiments, a plurality of ALD process stations 400 may be included in a low pressure process tool environment. For example, FIG. 4 depicts an embodiment of a multi-station processing tool 400. In some embodiments, one or more hardware parameters of ALD process station 400 including those discussed in detail below may be adjusted programmatically by one or more computer controllers 450.

ALD process station 400 fluidly communicates with reactant delivery system 401a for delivering process gases to a showerhead 406. Reactant delivery system 401a includes a mixing vessel 404 for blending and/or conditioning process gases, such as a silicon-containing precursor gas, or oxygen-containing and/or nitrogen-containing gas, for delivery to showerhead 406. One or more mixing vessel inlet valves 420 may control introduction of process gases to mixing vessel 404. One or more valves 405 may control introduction of gases to the showerhead 406.

As an example, the embodiment of FIG. 4 includes a vaporization point 403 for vaporizing liquid reactant to be supplied to the mixing vessel 404. In some embodiments, vaporization point 403 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 403 may be heat traced. In some examples, mixing vessel (not shown) may also be heat traced. In one non-limiting example, piping downstream of vaporization point 403 has an increasing temperature profile extending from approximately 40° C. to approximately 55° C. or from about 60° C. to about 65° C. at mixing vessel.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 403. In one scenario, a liquid injector may be mounted directly to mixing vessel. In another scenario, a liquid injector may be mounted directly to showerhead 406.

In some embodiments, a liquid flow controller (LFC) upstream of vaporization point 403 may be provided for controlling a mass flow of liquid for vaporization and delivery to ALD process station 400. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 406 distributes process gases toward substrate 412. In the embodiment shown in FIG. 4, the substrate 412 is located beneath showerhead 406 and is shown resting on a pedestal 408. Showerhead 406 may have any suitable shape, and may have any suitable number and arrangement of ports for distributing process gases to substrate 412.

In some embodiments, pedestal 408 may be raised or lowered to expose substrate 412 to a volume between the substrate 412 and the showerhead 406. It will be appreciated that, in some embodiments, pedestal height may be adjusted programmatically by a suitable computer controller 450.

In another scenario, adjusting a height of pedestal 408 may allow a plasma density to be varied during plasma activation in the process in embodiments where a plasma is ignited. At the conclusion of the process phase, pedestal 408 may be lowered during another substrate transfer phase to allow removal of substrate 412 from pedestal 408.

In some embodiments, pedestal 408 may be temperature controlled via heater 410. In some embodiments, the pedestal 408 may be heated to a temperature of about 25° C. to about 800° C., or about 200° C. to about 700° C., during deposition of silicon oxide films as described in disclosed embodiments. In some embodiments, the pedestal is set at a temperature of about 45° C. to about 800° C., or about 200° C. to about 300° C. In some embodiments, the same pedestal 408 is used for annealing.

Further, in some embodiments, pressure control for ALD process station 400 may be provided by butterfly valve 418. As shown in the embodiment of FIG. 4, butterfly valve 418 throttles a vacuum provided by a downstream vacuum pump (not shown). However, in some embodiments, pressure control of ALD process station 400 may also be adjusted by varying a flow rate of one or more gases introduced to the ALD process station 400.

In some embodiments, a position of showerhead 406 may be adjusted relative to pedestal 408 to vary a volume between the substrate 412 and the showerhead 406. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers 450.

In some embodiments where plasma may be used as discussed above, showerhead 406 and pedestal 408 electrically communicate with a radio frequency (RF) power supply 414 and matching network 416 for powering a plasma. For example, plasma may be used for treating a silicon oxide surface prior to depositing silicon nitride. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are about 150 W to about 10000 W or about 150 W to about 1500 W for a single-station chamber. For a 4-station chamber, the plasma power may include four generators each powered up to about 10000 W, for a total of about 40000 W. For annealing a silicon oxide film, the substrate may be exposed to a nitrogen-containing gas, or a mixture of nitrogen-containing gases and optional inert gases while igniting a plasma using the RF power supply 414 and matching network 416.

In some embodiments, the substrate may be exposed to nitrogen-containing gas while igniting a plasma to anneal silicon oxide using plasma powers such as between about 500 W and about 10000 W per surface area of a 300 mm wafer. The plasma may be generated remotely (such as in a remote plasma generator) or directly in a chamber housing the substrate (i.e. in situ). RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 0 KHz and 500 kHz. Example high-frequency RF frequencies may include, but are not limited to, frequencies between 1.8 MHz and 4.45 GHZ, or greater than about 13.56 MHz, or greater than 27 MHz. or greater than 30 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 450 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of a silicon-containing gas, instructions for setting a flow rate of a carrier gas (such as argon), and time delay instructions for the first recipe phase. A second recipe phase may include modulating or stopping a flow rate of an inert and/or a reactant gas, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of an oxygen-containing or nitrogen-containing gas and time delay instructions for the third recipe phase. A fourth recipe phase may include instructions for modulating or stopping a flow rate of an inert and/or a reactant gas, instructions for modulating the flow rate of a carrier or purge gas, and time delay instructions for the fourth recipe phase. A fifth, subsequent recipe phase may include instructions for setting a flow rate of a etching gas to form an angular structure such as a V-shaped structure, instructions for optionally heating or igniting a plasma, and instructions for modulating a flow rate of a carrier or purge gas and time delay instructions for the fifth recipe phase. A sixth, subsequent recipe phase may include instructions for setting a flow rate of a deposition gas and/or reactant gas, instructions for heating or igniting a plasma, and instructions for modulating a flow rate of a carrier or purge gas and time delay instructions for the fifth recipe phase. It will be appreciated that these recipe phases may be further subdivided and/or iterated in any suitable way within the scope of the disclosed embodiments. In some embodiments, the controller 450 may include any of the features described below with respect to system controller 550 of FIG. 5 and system controller 450 of FIG. 4.

A process station may be included in a single-station chamber or single-chamber tool such as shown in FIG. 5. FIG. 5 depicts an example processing apparatus according to disclosed embodiments. Tool 500 includes a processing chamber 514 which includes a processing station 590 may process a wafer. The processing chamber 514 is configured to deposit silicon oxide, deposit silicon nitride, anneal substrates using thermal or plasma anneals, and the like.

Tool 500 also includes a wafer transfer unit configured to transport wafers within the tool 500. Additional features of tool 500 will be discussed in greater detail below, and various features are discussed here with respect to some of the described techniques. In the depicted illustration, the wafer transfer unit includes a first robotic arm unit 526 in a first wafer transfer module and a second robotic arm unit 506 in a second wafer transfer module that may be considered an equipment front end module (EFEM) configured to received containers for wafers, such as a front opening unified module (FOUP) 508. The first robotic arm unit 526 is configured to transport a wafer between the processing chamber 514 and the second robotic arm unit via module 504 which may hold multiple wafers such as shown in module 502 with substrate 512. The second robotic arm unit 506 is configured to transport the wafer between a FOUP and module 504, or from module 502 to FOUP. After a wafer has been prepared in the module 504, the wafer transfer unit is able to transfer the wafer to first processing chamber 514 for deposition and optional anneal in situ.

Similar to above, the first wafer transfer module may a vacuum transfer module (VTM). Airlock or module 504, also known as a loadlock, is shown and may be individually optimized to perform various fabrication processes. The tool 500 also includes a FOUP 508 which, in some embodiments, may be purged using nitrogen while wafers are processed in the processing chamber 514. This includes maintaining the processing chamber 514, and the first wafer transfer module at the vacuum or low pressure. The second wafer transfer module may be at a different pressure, such as atmospheric. As the wafer is transferred throughout the tool 500, it is therefore maintained at the vacuum or low pressure.

In a further example, a substrate is placed in one of the FOUPs 508 and the second robot arm unit 506, or front-end robot. transfers the substrate from the FOUP 418 to an aligner, which allows the substrate to be properly centered before it is etched, or deposited upon, or otherwise processed. After being aligned, the substrate is moved by the second robot arm unit 506 into the airlock module 504. Because airlock modules have the ability to match the environment between an ATM and a VTM, the substrate is able to move between the two pressure environments without being damaged. From the airlock module 504, the substrate is moved by the first robot arm unit 526 through the first wafer transfer module, or VTM, and into the processing chamber 514. In order to achieve this substrate movement, the first robot arm unit 526 uses end effectors on each of its arms.

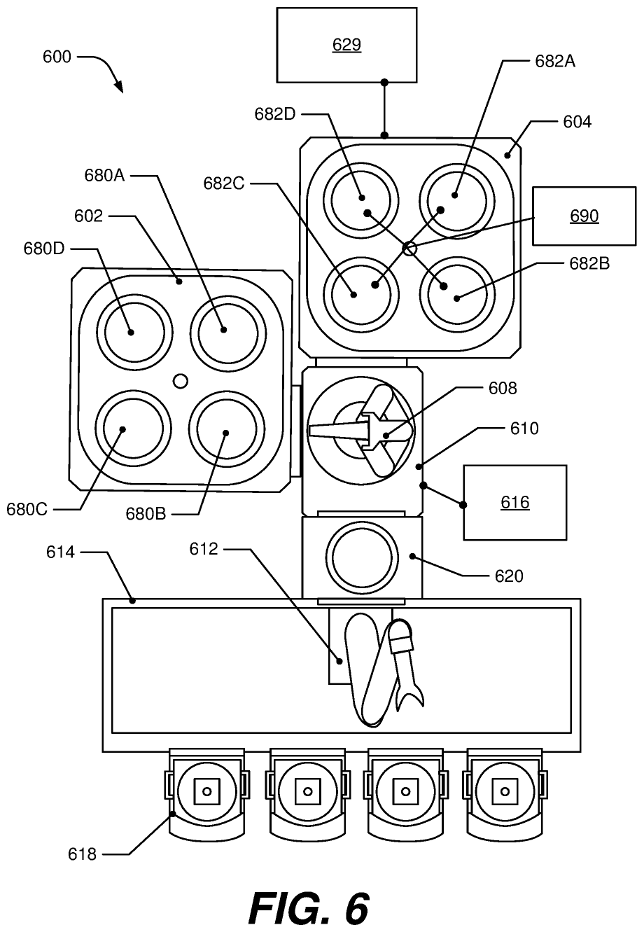

FIG. 5 also depicts an embodiment of a system controller 550 employed to control process conditions and hardware states of process tool 500. System controller 550 may include one or more memory devices 556, one or more mass storage devices 554, and one or more processors 552. Processor 552 may include a CPU or computer, analog and/or digital input/output connections, stepper motor controller boards, etc. In some embodiments, system controller 550 includes machine-readable instructions for performing operations such as those described above with respect to FIG. 6 and below with respect to FIG. 6.

As described above, one or more process stations may be included in a multi-station processing tool. FIG. 6 depicts an example processing apparatus according to disclosed embodiments. Tool 600 includes a first processing chamber 602 and a second processing chamber 604. While two processing chambers are depicted, it will be understood that in some embodiments, additional processing chambers may be used. For example, in some embodiments, three processing chambers may be used. The first processing chamber 602 includes a plurality of processing stations, four stations 680A-D, that each may process a wafer. The first processing chamber 602 is configured to perform plasma treatment operations on the wafers. The second processing chamber 604 is configured to perform deposition on the wafer and may be considered a deposition chamber. The second processing chamber 604 also includes a plurality of processing stations, four stations 682A-D, that each may process a wafer. The first and second processing chambers 602 and 604 may be considered multi-station processing chambers.

Tool 600 also includes a wafer transfer unit configured to transport one or more wafers within the tool 600. Additional features of tool 600 will be discussed in greater detail below, and various features are discussed here with respect to some of the described techniques. In the depicted illustration, the wafer transfer unit includes a first robotic arm unit 608 in a first wafer transfer module 610 and a second robotic arm unit 612 in a second wafer transfer module 614 that may be considered an equipment front end module (EFEM) configured to received containers for wafers, such as a front opening unified module (FOUP) 616. The first robotic arm unit 608 is configured to transport a wafer between the first processing chamber 602 and the second processing chamber 604, and between the second the second robotic arm unit 612. The second robotic arm unit 612 is configured to transport the wafer between a FOUP and the first robotic arm unit 608. After a wafer has been treated in the first processing chamber 602, the wafer transfer unit is able to transfer the wafer from the first processing chamber 602, to the second processing chamber 604 where one or more layers of encapsulation material may be deposited on one or more wafers.

Similar to above, the first wafer transfer module 610 may a vacuum transfer module (VTM). Airlock 620, also known as a loadlock or transfer module, is shown and may be individually optimized to perform various fabrication processes. The tool 600 also includes a FOUP 616 that is configured to lower the pressure of the tool 600 to a vacuum or low pressure, e.g., between about 1 mTorr and about 10 Torr, and maintain the tool 600 at this pressure. This includes maintaining the first and second processing chambers 602 and 604, and the first wafer transfer module 610 at the vacuum or low pressure. The second wafer transfer module 614 may be at a different pressure, such as atmospheric. As the wafer is transferred throughout the tool 600, it is therefore maintained at the vacuum or low pressure. For example, as the wafer is transferred from the first processing chamber 602, into the first wafer transfer module 610, and to the second processing chamber 604, the wafer is maintained at the vacuum or low pressure and not exposed to atmospheric pressure.

In a further example, a substrate is placed in one of the FOUPs 618 and the second robot arm unit 612, or front-end robot, transfers the substrate from the FOUP 618 to an aligner, which allows the substrate to be properly centered before it is etched, or deposited upon, or otherwise processed. After being aligned, the substrate is moved by the second robot arm unit 612 into the airlock 620. Because airlock modules have the ability to match the environment between an ATM and a VTM, the substrate is able to move between the two pressure environments without being damaged. From the airlock 620, the substrate is moved by the first robot arm unit 608 through the first wafer transfer module 610, or VTM 610, and into the first processing chamber 602. In order to achieve this substrate movement, the first robot arm unit 608 uses end effectors on each of its arms.

FIG. 6 also depicts an embodiment of a system controller 629 employed to control process conditions and hardware states of tool 600. System controller 629 may include one or more memory devices (not shown), one or more mass storage devices (not shown), and one or more processors (not shown). Processors may include a CPU or computer, analog, and/or digital input/output connections, stepper motor controller boards, etc.

In some embodiments, system controller 629 controls all of the activities of tool 600. System controller 629 executes system control software stored in mass storage device, loaded into memory device, and executed on processor. Alternatively, the control logic may be hard coded in the system controller 629. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software may include instructions for controlling the timing, mixture of gases, gas flow rates, chamber and/or station pressure, chamber and/or station temperature, wafer temperature, target power levels, RF power levels, substrate pedestal, chuck and/or susceptor position, and parameters of a particular process performed by tool 600. System control software may be configured in any suitable way. For example, various process tool component subroutines or control objects may be written to control operation of the process tool components used to carry out various process tool processes. System control software may be coded in any suitable computer readable programming language.

In some embodiments, system control software may include input/output control (IOC) sequencing instructions for controlling the various parameters described above. Other computer software and/or programs stored on mass storage device and/or memory device associated with system controller 629 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal and to control the spacing between the substrate and other parts of tool 600.

A process gas control program may include code for controlling gas composition (e.g., silicon-containing precursor gases, nitrogen-containing gases, carrier gases, inert gases, and/or purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium or nitrogen) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 629. The user interface may include a display screen, graphical software displays of the apparatus and/or process conditions, and user input devices such as pointing devices, keyboards, touch screens, microphones, etc.

In some embodiments, parameters adjusted by system controller 629 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 629 from various process tool sensors. The signals for controlling the process may be output on the analog and digital output connections of tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 629 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 629 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 629.

In some implementations, the system controller 629 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 629, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 629 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 629 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 629, in some implementations, may be a part of or coupled to a computer that is integrated with, coupled to the system, otherwise networked to the system, or a combination thereof. For example, the system controller 629 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 629 receives instructions in the form of data, which specify parameters for each of the processing steps to be performed during one or more operations. It should be understood that the parameters may be specific to the type of process to be performed and the type of tool that the system controller 629 is configured to interface with or control. Thus as described above, the system controller 629 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers. As noted above, depending on the process step or steps to be performed by the tool, the system controller 629 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

An appropriate apparatus for performing the methods disclosed herein is further discussed and described in U.S. patents application Ser. Nos. 13/084,399 (now U.S. Pat. No. 8,728,956), filed Apr. 11, 2011, and titled “PLASMA ACTIVATED CONFORMAL FILM DEPOSITION”; and Ser. No. 13/084,305, filed Apr. 11, 2011, and titled “SILICON NITRIDE FILMS AND METHODS,” each of which is incorporated herein in its entireties.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Experimental

An experiment was conducted on wafers having multiple negative features therein. The features were partially filled using atomic layer deposition (ALD), leaving a gap in the center of the feature. A first substrate was exposed to 400 seconds of dual frequency plasma with HF power of 2000 W and LF power of 3000 W, which resulted in an angular opening such as a V-shaped opening at or near the feature openings. A second substrate was exposed to 800 seconds dual frequency plasma with HF power of 2000 W and LF power of 3000 W, which resulted in an angular opening such as a V-shaped opening at or near the feature openings having a wider critical dimension opening and deeper V-shape having steeper slope as compared to the first substrate. A third substrate was exposed to 400 seconds dual frequency plasma with HF power of 500 W and LF power of 3000 W, which resulted in a V-shaped opening (about 60°) at or near the feature openings with a narrower critical dimension and less steep slope on sidewalls at or near the feature openings compared to the first and second substrates. A fourth substrate was exposed to 800 seconds dual frequency plasma with HF power of 500 W and LF power of 3000 W, which resulted in a V-shaped opening at or near the feature openings with a wider critical dimension than the third substrate and less steep slope on sidewalls at or near the feature openings compared to the first and second substrates (about 55°).

### Definitions and Precursors

### Definitions

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), I-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)-OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁-10), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁-6 alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O))— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ Or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR₁, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—).

In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently. C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66 (1): 1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

As used herein, the term “about” means +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### Precursors

The film can be deposited using any useful silicon-containing precursor (Si-containing precursor). Silicon-containing precursors suitable for use in accordance with disclosed embodiments include polysilanes (H₃Si—(SiH₂)ₙ—SiH₃), where n≥0. Examples of silanes are silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials when a plasma is struck, a halosilane may not be introduced to the chamber when a plasma is struck in some embodiments, so formation of a reactive halide species from a halosilane may be mitigated. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, 1-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bi(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)). In some embodiments, the precursor includes a structure of formula (I):

Si(R′)₄ (I),

wherein at least one R′ includes a carbon atom. In other embodiments, at least one R′ includes a heteroatom (e.g., nitrogen, oxygen, and/or silicon). In yet other embodiments, at least one R′ includes a carbon atom and a heteroatom (e.g., nitrogen, oxygen, and/or silicon). In particular embodiments, R′ does not include a halogen atom.

In other embodiments, the precursor includes a structure of formula (II):

(R′)₃Si-[L-Si(R′)₂]—R′ (II),

wherein at least one R′ includes a carbon atom and L is a linker. In some embodiments, at least one R′ includes a heteroatom (e.g., nitrogen, oxygen, and/or silicon). In yet other embodiments, at least one R′ includes a carbon atom and a heteroatom (e.g., nitrogen, oxygen, and/or silicon). In particular embodiments, R′ does not include a halogen atom.

For formula (II), non-limiting linkers for L include a covalent bond, oxy (—O—), carbonyl (—C(O)—), optionally substituted carbonimidoyl (e.g., —C(NR)—), optionally substituted imino (e.g., —NR—), an optionally substituted alkylene, optionally substituted heteroalkylene, optionally substituted arylene, and the like.

For any formula herein (e.g., for formula (I) or (II)), R′ can be H, aliphatic, heteroaliphatic, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato (—OCN), isocyanato (—NCO), cyano (—CN), or isocyano (—NC), in which any of these may be optionally substituted.

In particular embodiments, at least one, two, three, four, or more R′ in any formula herein (e.g., for formula (I) or (II)) includes an optionally substituted aliphatic. Non-limiting aliphatic groups include alkyl, alkenyl, or alkynyl, including linear, branched, cyclic, saturated, or unsaturated forms thereof. Such groups can be unsubstituted or substituted, such as with one or more substituents described herein for alkyl. Further examples of aliphatic groups include methyl (Me), ethyl (Et), propyl (Pr), iso-propyl (iPr), cyclopropyl (cPr), butyl (Bu), sec-butyl (sBu), iso-butyl (iBu), tert-butyl (tBu), pentyl (Pe), tert-pentyl (tPe), allyl (All), vinyl (Vi), ethynyl, and the like.

In some embodiments, at least one, two, three, four, or more R′ in any formula herein (e.g., for formula (I) or (II)) includes an optionally substituted heteroaliphatic. A heteroaliphatic group can include any including one or more carbon atoms and one or more heteroatoms (e.g., oxygen, nitrogen, and the like).

Non-limiting heteroaliphatic groups includes aliphatic-carbonyl (e.g., alkanoyl or —C(O)R^{Ak}), aliphatic-carbonyloxy (e.g., alkanoyloxy or —OC(O)R^{Ak}), aliphatic-oxy (e.g., alkoxy or —OR^{Ak}), aliphatic-oxycarbonyl (e.g., alkoxycarbonyl or —C(O)OR^{Ak}), amino (e.g., —NR^{N1}R^{N2}), aromatic-carbonyl (e.g., aryloyl or —C(O)R^{Ar}), aromatic-carbonyloxy (e.g., aryloyloxy or —OC(O)R^{Ar}), aromatic-oxy (e.g., aryloxy or —OR^{Ar}), aromatic-oxycarbonyl (e.g., aryloxycarbonyl or —C(O)OR^{Ar}), imidoyl (e.g., —C(NR^{N1}) H, —C(NR^{N1})R^{Ak}, or —C(NR^{N1})R^{Ar}), carbamoyl (e.g., —C(O)NR^{N1}R^{N2}), carbamoyloxy (e.g., —OC(O)NR^{N1}R^{N2}), carboxyl (—CO₂H), formyl (—C(O)H), heteroaromatic, heterocyclyl (e.g., optionally substituted furanyl, tetrahydrofuranyl, pyrrolidinyl, pyrrolyl, imidazolyl, pyrazolyl, triazolyl, piperidinyl, pyridinyl, pyrimidinyl, pyridazinyl, pyrazinyl, oxazolyl, morpholinyl, and the like), hydrazino (e.g., —NR^{N1}—NR^{N2}R^{N3}), silyl (e.g., —SiR^{S1}R^{S2}R^{S3}), and silyloxy (e.g., —O—SiR^{S1}R^{S2}R^{S3}). Each of these groups can be optionally substituted with any substituent described herein (e.g., as described herein for alkyl).

Heteroaliphatic groups can include linear, branched, cyclic (e.g., heterocyclyl), saturated, or unsaturated forms thereof.

Heteroaliphatic groups can include R^{Ak} and/or R^{Ar} moieties. In some embodiments, R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl. In other embodiments, R^{Ar} is optionally substituted aromatic, optionally substituted heteroaromatic, optionally substituted aryl, or optionally substituted heteroaryl.

Nitrogen-containing groups (e.g., amino, imidoyl, etc.) can include R^{N1}, R^{N2}, and/or R^{N3} moieties attached to a nitrogen atom. In some embodiments, each of R^{N1}, R^{N2}, and R^{N3} is, independently, H, optionally substituted aliphatic, optionally substituted heteroaliphatic, optionally substituted aromatic, optionally substituted heteroaromatic, optionally substituted silyl, or optionally substituted silyloxy. In particular embodiments. R^{N1} and R^{N2} or R^{N2} and R^{N3} can be taken together, with the nitrogen atom to which each is attached, to form an optionally substituted heterocyclyl. Such nitrogen-containing groups can be included within other moieties, such as within silyl or silyloxy groups.

Silicon-containing groups (e.g., silyl, etc.) can include R^{S1}, R^{S2}, and/or R^{S3} attached to a silicon atom. In some embodiments, each of R^{S1}, R^{S2}, and R^{S3} is, independently, H, optionally substituted aliphatic, optionally substituted heteroaliphatic, optionally substituted aromatic, optionally substituted heteroaromatic, or optionally substituted amino. Such silicon-containing groups can be included within other moieties, such as within amino groups.

In some embodiments, the silyl group is an alkylsilyl group having one or more aliphatic groups attached to the silicon atom. In one instance, the alkylsilyl group is —Si(R)ₐ(R^{Ak})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; a≥0; b≥1; and a+b=3. Yet other non-limiting alkylsilyl groups include —SiH₂R^{Ak}, —SiH[R^{Ak}]₂, or —Si[R^{Ak}]₃, in which R^{Ak} is any provided herein.

In some embodiments, the silyl group is an alkoxysilyl group having one or more aliphatic groups attached to the silicon atom by way of an oxy (—O—) group. In one instance, the alkoxylsilyl group is —Si(R)ₐ(OR^{Ak})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; a≥0; b≥1; and a+b=3. Yet other non-limiting alkoxysilyl groups include —SiH₂[OR^{Ak}], —SiH[OR^{Ak}]₂, or —Si[OR^{Ak}]₃, in which R^{Ak} is any described herein.

In other embodiments, the silyl group is an arylsilyl group having one or more aromatic groups attached to the silicon atom. In one instance, the arylsilyl group is —Si(R)ₐ(R^{Ar})_{b}, in which R is, independently, H, aliphatic, heteroaliphatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ar} is optionally substituted aromatic, optionally substituted heteroaromatic, optionally substituted aryl, or optionally substituted heteroaryl; a≥0; b≥1; and a+b=3. Yet other non-limiting arylsilyl groups include —SiH₂R^{Ar}, —SiH[R^{Ar}]₂, or —Si[R^{Ar}]₃, in which R^{Ar} is any described herein.

In yet other embodiments, the silyl group is an aryloxysilyl group having one or more aromatic groups attached to the silicon atom by way of an oxy (—O—) group. In one instance, the arylsilyl group is —Si(R)ₐ(OR^{Ar})_{b}, in which R is, independently, H, aliphatic, heteroaliphatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ar} is optionally substituted aromatic, optionally substituted heteroaromatic, optionally substituted aryl, or optionally substituted heteroaryl; a≥0; b≥1; and a+b=3. Yet other non-limiting aryloxysilyl groups include —SiH₂[OR^{Ar}], —SiH[OR^{Ar}]₂, or —Si[OR^{Ar}]₃, in which R^{Ar} is any described herein.

A silyl group can also include an aminosilyl having one or more optionally substituted amino groups attached to the silicon atom. In one instance, the aminosilyl group is —Si(R)ₐ(NR^{N1}R^{N3})_{b}, in which R is, independently, H, aliphatic, heteroaliphatic, aromatic, heteroaromatic, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; each of R^{N1} and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; a≥0; b≥1; and a+b=3. Yet other non-limiting embodiments of aminosilyl groups include —SiH₂[NR^{N1}R^{N2}], —SiH[R^{Ak}][NR^{N1}R^{N2}], —Si[R^{Ak}]₂[NR^{N1}R^{N2}], —SiH[NR^{N1}R^{N2}]₂, —Si[R^{Ak}][NR^{N1}R^{N2}]₂, or —Si[NR^{N1}R^{N2}]₃), such as —SiH₂[NH₂], —SiHR^{Ak}[NH₂], —Si[R^{Ak}]₂[NH₂], —SiH₂[NH(R^{Ak})], —SiHR^{Ak}[NH(R^{Ak})], —Si[R^{Ak}], [NH(R^{Ak})], —SiH₂[N(R^{Ak})₂], —SiHR^{Ak}[N(R^{Ak})₂], —Si[R^{Ak}], [N(R^{Ak})₂], —SiH[NH₂]₂, —SiR^{Ak}[NH₂]₂, —SiH[NH(R^{Ak})]₂, —SiR^{Ak}[NH(R^{Ak})]₂, —SiH[NH(R^{Ak})][NH₂], —SiR^{Ak}[NH(R^{Ak})][NH₂], —SiH[N(R^{Ak})₂]₂, —SiR^{Ak}[N(R^{Ak})₂]₂, —SiH[N(R^{Ak})₂][NH₂], —SiR^{Ak}[N(R^{Ak})₂][NH₂], —Si[NH₂]₃, —Si[N(R^{Ak})₂][NH₂]₂, —Si[N(R^{Ak})₂]₂[NH₂], —Si[N(R^{Ak})₂]₃, —Si[NH(R^{Ak})][NH₂]₂, —Si[NH(R^{Ak})₂]₂[NH₂], —Si[NH(R^{Ak})]₃, —Si[NH(R^{Ak})][N(R^{Ak})₂]₂, —Si[NH(R^{Ak})]₂[N(R^{Ak})₂], and the like, in which R^{Ak} is optionally substituted aliphatic, heteroaliphatic, alkyl, alkenyl, alkynyl, or alkoxy; and each of R^{N1} and R^{N2} is any described herein.

In some embodiments, the silyl group is —Si(R′)ₐ(OR)_{b}(NR₂)_{c}, in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

In other embodiments, any of the silyl groups herein can be attached to the parent compound through an oxy bond. In some embodiments, the silyloxy group is —O—Si(R′)ₐ(OR)_{b}(NR₂)_{c}, in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl. Yet other non-limiting silyloxy groups include —O—Si(R)ₐ(R^{Ak})_{b}, —O—Si(R)ₐ(OR^{Ak})_{b}, —O—Si(R)ₐ(R^{Ar})_{b}, —O—Si(R)ₐ(OR^{Ar})_{b}, —O—Si(R)ₐ(NR^{N1}R^{N2})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; R^{Ar} is optionally substituted aromatic, optionally substituted heteroaromatic, optionally substituted aryl, or optionally substituted heteroaryl; each of R^{N1} and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; a≥0; b≥1; and a+b=3. Yet other non-limiting silyloxy groups include alkylsilyloxy (e.g., —O—SiH₂R^{Ak}, —O—SiH[R^{Ak}]₂, or —O—Si[R^{Ak}]₃); alkoxysilyloxy (e.g., —O—SiH₂[OR^{Ak}], —O—SiH[OR^{Ak}]₂, or —O—Si[OR^{Ak}]₃); arylsilyloxy (e.g., —O—SiH₂R^{Ar}, —O—SiH[R^{Ar}]₂, or —O—Si[RA]₃); or aryloxysilyloxy (e.g., —O—SiH₂[OR^{Ar}], —O—SiH[OR^{Ar}]₂, or —O—Si[OR^{Ar}]₃). In some embodiments, the silyl group is aminosilyloxy (e.g., —O—SiH₂[NR^{N1}R^{N2}], —O—SiH[R^{Ak}][NR^{N1}R^{N2}], —O—Si[R^{Ak}], [NR^{N1}R^{N2}], —O—SiH[NR^{N1}R^{N2}]₃, —O—Si[R^{Ak}][NR^{N1}R^{N2}]₂, or —O—Si[NR^{N1}R^{N2}]₃).

Silyl and silyloxy group can have a mixed combination of aliphatic and aromatic groups. In one instance, the silyl group is —Si(R)ₐ(R^{Ak})_{b}(R^{Ar})_{c} or —Si(R)ₐ(OR^{Ak})_{b}(OR^{Ar})_{c}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic (e.g., optionally substituted alkyl) or optionally substituted heteroaliphatic (e.g., optionally substituted alkoxy or optionally substituted amino); R^{Ar} is optionally substituted aromatic or optionally substituted heteroaromatic; each of a, b, and c≥0; and a+b+c=3.

In another instance, the silyl group is —Si(R)ₐ(NR^{Ak}₂)_{b}, —Si(R)ₐ(NR^{Ak}R^{Ar})_{b}, or —Si(R)ₐ(NR^{Ar}₂)_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; each of R^{N1} and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; each of a and b≥0; and a+b=3.

In yet another instance, the silyloxy group is —O—Si(R)ₐ(R^{Ak})_{b}(R^{Ar})_{c}, —O—Si(R)ₐ(OR^{Ak})_{b}(OR^{Ar})_{c}, —O—Si(R)ₐ(NR^{Ak}₂)_{b}, —O—Si(R)ₐ(NR^{Ak}R^{Ar})_{b}, or —O—Si(R)ₐ(NR^{Ar}₂)_{b}, in which R, R^{Ak}, and R^{Ar} are any described herein; and a, b, and c are any described herein.

In some embodiments, at least one, two, three, four, or more R′ in any formula herein (e.g., for formula (I) or (II)) includes an optionally substituted aliphatic-oxy, heteroaliphatic-oxy, aromatic-oxy, or heteroaromatic-oxy. For instance, R′ can be —O—R, in which R is optionally substituted aliphatic (e.g., alkyl, alkenyl, alkynyl, cycloalkyl, cycloalkenyl, or cycloalkynyl), optionally substituted heteroaliphatic (e.g., heteroalkyl, heteroalkenyl, heteroalkynyl, or heterocyclyl), optionally substituted aromatic (e.g., aryl), optionally substituted heteroaromatic (e.g., heteroaryl), optionally substituted aliphatic-carbonyl (e.g., alkanoyl or —C(O)R^{Ak}, in which R^{Ak} is optionally substituted aliphatic or any described herein), optionally substituted silyl (e.g., —SiR^{S1}R^{S2}R^{S3} or —Si(R′)ₐ(OR)_{b}(NR₂)_{c}, including any described herein), or optionally substituted amino (e.g., —NR^{N1}R^{N2}, including any described herein).

In particular embodiments, at least one, two, three, four, or more R′ in any formula herein (e.g., for formula (I) or (II)) includes an optionally substituted aromatic or optionally substituted heteroaromatic. Non-limiting aromatic and heteroaromatic groups include phenyl, benzyl, naphthyl, furanyl, pyrrolyl, imidazolyl, pyrazolyl, triazolyl, pyridinyl, pyrimidinyl, pyridazinyl, pyrazinyl, oxazolyl, and the like.

In particular embodiments, at least one, two, three, four, or more R′ in any formula herein (e.g., for formula (I) or (II)) includes an optionally substituted amino (e.g., —NH₂, —NR^{N1}H, or —NR^{N1}R^{N2}). In particular embodiments, each of R^{N1} and R^{N2} is, independently, H, optionally substituted aliphatic, optionally substituted heteroaliphatic, optionally substituted aromatic, optionally substituted heteroaromatic, optionally substituted amino, hydroxyl, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R^{N1} and R^{N2} can be taken together, with the nitrogen atom to which each is attached, to form an optionally substituted heterocyclyl.

Non-limiting instances of R^{N1} and R^{N2} can include H, aliphatic, alkyl (e.g., —R^{Ak}), alkenyl, alkynyl, aliphatic carbonyl (e.g., alkanoyl or —C(O)R^{Ak}), aliphatic-carbonyloxy (e.g., alkanoyloxy or —OC(O)R^{Ak}), aliphatic-oxy (e.g., alkoxy or —OR^{Ak}), aliphatic-oxycarbonyl (e.g., alkoxycarbonyl or —C(O)OR^{Ak}), amino (e.g., —NR², in which each R is, e.g., H, optionally substituted aliphatic, optionally substituted heteroaliphatic, optionally substituted aromatic, or optionally substituted heteroaromatic), aromatic (e.g., aryl or —R^{Ar}), aromatic-carbonyl (e.g., aryloyl or —C(O)R^{Ar}), aromatic-carbonyloxy (e.g., aryloyloxy or —OC(O)R^{Ar}), aromatic-oxy (e.g., aryloxy or —OR^{Ar}), aromatic-oxycarbonyl (e.g., aryloxycarbonyl or —C(O)OR^{Ar}), imidoyl (e.g., —C(NR) H, —C(NR)R^{Ak}, or —C(NR)R^{Ar}, in which each R is, e.g., H, optionally substituted aliphatic, optionally substituted heteroaliphatic, optionally substituted aromatic, or optionally substituted heteroaromatic), carbamoyl (e.g., —C(O)NR², in which each R is, e.g., H, optionally substituted aliphatic, optionally substituted heteroaliphatic, optionally substituted aromatic, or optionally substituted heteroaromatic), carbamoyloxy (e.g., —OC(O)NR², in which each R is, e.g., H, optionally substituted aliphatic, optionally substituted heteroaliphatic, optionally substituted aromatic, or optionally substituted heteroaromatic), carboxyl (—CO₂H), formyl (—C(O)H), heteroaromatic, heterocyclyl (e.g., optionally substituted furanyl, tetrahydrofuranyl, pyrrolidinyl, pyrrolyl, imidazolyl, pyrazolyl, triazolyl, piperidinyl, pyridinyl, pyrimidinyl, pyridazinyl, pyrazinyl, oxazolyl, morpholinyl, and the like), hydroxyl (—OH), silyl (e.g., —SiR^{S1}R^{S2}R^{S3} or —Si(R′)ₐ(OR)_{b}(NR₂)_{c}), and silyloxy (e.g., —O—SiR^{S1}R^{S2}R^{S3} or —O—Si(R′)ₐ(OR)_{b}(NR₂)_{c}). For any of these groups, where indicated, R^{Ak}, R^{Ar}, R′, R, R^{S1}, R^{S2}, R^{S3}, a, b, and c can be any described herein.

Yet other non-limiting amino groups include —NH₂, —NHMe, —NMe₂, —NHEt, —NMeEt, —NEt, —NHnPr, —NMenPr, —NnPr₂, —NHiPr, —NMeiPr, —NiPr₂, —NHsBu, —NMesBu, —NsBu₂, —NHtBu, —NMetBu, —NtBu₂, —N[SiH₃]₂, —N[Si(Me)₃]₂, —N[Si(Et)₃]₂, —NH[SiH₃], —NH[Si(Me)₃], —NH[Si(Et)₃], —NMe[SiH₃], —NMe[Si(Me)₃], —NMe[Si(Et)₃], —N[SiH₂Me]₂, —N[SiHMe₂]₂, —N[SiH₂Et]₂, —N[SiHEt₂]₂, —N[SiHMeEt]₂, —NH[SiH₂Me], —NH[SiHMe₂], —NH[SiH₂Et], —NH[SiHEt₂]₂, —NH[SiHMeEt], —NMe[SiH₂Me], —NMe[SiHMe₂], —NMe[SiH₂Et], —NMe[SiHEt₂]₂, —NMe[SiHMeEt], and the like.

In particular embodiments, at least one, two, three, four, or more R′ in any formula herein (e.g., for formula (I) or (II)) includes an optionally substituted hydrazino (e.g., —NH—NH₂ or —NR^{N1}—NR^{N2}R^{N3}). In particular embodiments, each of R^{N1}, R^{N2}, and R^{N3} is, independently, H, optionally substituted aliphatic, optionally substituted heteroaliphatic, optionally substituted aromatic, optionally substituted heteroaromatic, optionally substituted amino, hydroxyl, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R^{N1} and R^{N2} or R^{N2} and R^{N3} can be taken together, with the nitrogen atom to which each is attached, to form an optionally substituted heterocyclyl. Yet other non-limiting hydrazino groups include —NH—NH₂, —NMe-NH₂, —NH—NHMe, —NH—NMe₂, —NMe-NMe₂, —NEt-NH₂, —NH—NHEt, —NH-NEt₂, —NMe-NEt₂, and the like.

In some embodiments, at least one, two, three, four, or more R′ in any formula herein (e.g., for formula (I) or (II)) includes an optionally substituted silyl. In one embodiment, silyl is —SiR^{S1}R^{S2}R^{S3}, in which each of R^{S1}, R^{S2}, and R^{S3} is, independently, H, optionally substituted aliphatic, optionally substituted heteroaliphatic, optionally substituted aromatic, optionally substituted heteroaromatic, optionally substituted amino, optionally substituted hydrazino, azido, hydroxyl, optionally substituted silyl, optionally substituted silyloxy, optionally substituted alkyl, optionally substituted alkenyl, optionally substituted alkynyl, optionally substituted alkoxy, optionally substituted heteroalkyl, optionally substituted heteroalkenyl, optionally substituted heteroalkynyl, optionally substituted heterocyclyl, optionally substituted aryl, optionally substituted aryloxy, cyanato, isocyanato, cyano, isocyano, and the like. Non-limiting silyl groups include any described herein, such as —Si(R)ₐ(R^{Ak})_{b}, —Si(R)ₐ(OR^{Ak})_{b}, —Si(R)ₐ(R^{Ar})_{b}, —Si(R)ₐ(OR^{Ar})_{b}, —Si(R)ₐ(NR^{N1}R^{N2})_{b}, —Si(R′)ₐ(OR)_{b}(NR₂)_{c}, and the like. Yet other non-limiting silyl groups include —SiH₃, —SiH₂Me, —SiHMe₂, —SiMe₃, —Si(OH)₃, —SiH₂(OMe), —SiH(OMe)₂, —Si(OMe)₃, —SiH₂(NH₂), —SiHMe(NH₂), —SiMe₂ (NH₂), —SiH(NH₂)₂, —SiMe(NH₂)₂, —Si(NH₂)₃, —SiH₂(NMe₂), —SiH₂(NMe₂), —SiHMe(NMe₂), —Si(Me)₂(NMe₂)₂, —SiMe(NMe₂)₂, —Si(NMe₂)₃, —SiH₂(NHMe), —SiHMe(NHMe), —SiH(NHMe)₂, —SiMe(NHMe)₂, —Si(NHMe)₃, and the like.

In other embodiments, at least one, two, three, four, or more R′ in any formula herein (e.g., for formula (I) or (II)) includes an optionally substituted silyloxy. Non-limiting silyloxy groups include any described herein, such as —O—Si(R)ₐ(R^{Ak})_{b}, —O—Si(R)ₐ(OR^{Ak})_{b}, —O—Si(R)ₐ(R^{Ar})_{b}, —O—Si(R)ₐ(OR^{Ar})_{b}, —O—Si(R)ₐ(NR^{N1}R^{N2})_{b}, —O—Si(R′)ₐ(OR)_{b}(NR₂)_{c}, and the like. Yet other non-limiting silyloxy groups include —O—SiH₃, —O—SiH₂Me, —O—SiHMe₂, —O—SiMe₃, —O—Si(OH)₃, —O—SiH₂(OMe), —O—SiH(OMe)₂, —O—Si(OMe)₃, —O—SiH₂(NH₂), —O—SiHMe(NH₂), —O—SiMe₂ (NH₂), —O—SiH(NH₂)₂, —O—SiMe(NH₂)₂, —O—Si(NH₂)₃, —O—SiH 2 (NMe₂), —O—SiH₂(NMe₂), —O—SiHMe(NMe₂), —O—Si(Me)₂(NMe₂)₂, —O—SiMe(NMe₂)₂, —O—Si(NMe₂)₃, —O—SiH₂(NHMe), —O—SiHMe(NHMe), —O—SiH(NHMe)₂, —O—SiMe(NHMe)₂, —O—Si(NHMe)₃, and the like.

In yet other embodiments, at least one, two, three, four, or more R′ in any formula herein (e.g., for formula (I) or (II)) includes azido (—N₃), hydroxyl (—OH), cyanato (—OCN), isocyanato (—NCO), cyano (—CN), and/or isocyano (—NC).

The organic silicon-containing precursor may be selected from the group consisting of silane, disilane, trisilane, tetrasilane, amine-substituted versions of any of the foregoing silanes, and trisilylamine.

Examples of organic silicon-containing precursors include, but are not limited to, silanes, polysilanes, halosilanes, and aminosilanes. A silane contains hydrogen and/or carbon groups, but does not contain a halogen. A polysilane may have the formula (H₃Si—(SiH₂) n-SiH₃), where n≥1. Examples of silanes include silane (SiH₄), disilane (Si₂H₆), trisilane, tetrasilane and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, tetra-ethyl-ortho-silicate (also known as tetra-ethoxy-silane or TEOS) and the like.

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino)silane (DSBAS), di(isopropylamido)silane (DIPAS), bis(diethylamino)silane (BDEAS), and the like. A further example of an aminosilane is trisilylamine (N(SiH₃)₃).

Examples of silicon-containing precursors for depositing silicon carbide include siloxanes, alkyl silane or hydrocarbon-substituted silane, or a nitrogen-containing carbon-containing reactant. Examples of siloxanes include 2,4,6,8-tetramethylcyclotetrasiloxane (TMCTS), heptamethylcyclotetrasiloxane (HMCTS), silsesquioxane, disiloxanes, such as pentamethyldisiloxane (PMDSO) or tetramethyldisiloxane (TMDSO), and trisiloxanes such as hexamethyltrisiloxane or heptamethyltrisiloxane. Alkyl silanes include a central silicon atom with one or more alkyl groups bonded to it as well as one or more hydrogen atoms bonded to it. In some embodiments, any one or more of the alkyl groups contain 1-5 carbon atoms. The hydrocarbon groups may be saturated or unsaturated (e.g., alkene (e.g., vinyl), alkyne, and aromatic groups). Examples include but are not limited to trimethylsilane (3MS), triethylsilane, pentamethyl disilamethane ((CH₃)₂Si—CH₂—Si(CH₃)₃), and dimethylsilane (2MS). Additionally, disilanes, trisilanes, or other higher silanes may be used in place of monosilanes. In some embodiments, one of the silicon atoms can have a carbon-containing or hydrocarbon group attached to it, and one of the silicon atoms can have a hydrogen atom attached to it. Example carbon-containing reactants including a nitrogen include methyl-substituted disilazanes and trisilazanes, such as tetramethyldisilazane and hexamethyl trisilazane.

Yet other examples of organic silicon-containing precursors can include siloxanes such as cyclotetrasiloxanes such as heptamethylcyclotetrasiloxane (HMCTS) and tetramethyl cyclotetrasiloxane. Other cyclic siloxanes can also include but are not limited to cyclotrisiloxanes and cyclopentasiloxanes. Other examples of suitable precursors include linear siloxanes such as, but not limited to, disiloxanes, such as pentamethyldisiloxane (PMDSO), tetramethyldisiloxane (TMDSO), hexamethyl trisiloxane, and heptamethyl trisiloxane. For undoped silicon carbide, examples of suitable precursors include monosilanes substituted with one or more alkyl, alkene, and/or alkyne groups containing, e.g., 1-5 carbon atoms. Examples include but are not limited to trimethylsilane (3MS), dimethylsilane (2MS), triethylsilane (TES), and pentamethyldisilamethane. Additionally, disilanes, trisilanes, or other higher silanes may be used in place of monosilanes. An example of one such disilane from the alkyl silane class is hexamethyldisilane (HMDS). Another example of a disilane from the alkyl silane class can include pentamethyldisilane (PMDS). Other types of alkyl silanes can include alkylcarbosilanes, which can have a branched polymeric structure with a carbon bonded to a silicon atom as well as alkyl groups bonded to a silicon atom. Examples include dimethyl trimethylsilyl methane (DTMSM) and bis-dimethylsilyl ethane (BDMSE). Examples of other suitable precursors include, e.g., alkyldisilazanes and possibly compounds including amino (—NH₂) and alkyl groups separately bonded to one or more silicon atoms. Alkyldisilazanes include silizanes and alkyl groups bonded to two silicon atoms. An example includes 1,1,3,3-tetramethyldisilazane (TMDSN).

In the Si-containing precursors described herein, different kinds of R′ can be attached to the silicon atom. Further Si-containing precursors are described herein.

### Amino Silanes

A silicon-containing precursor can include one or more optionally substituted amino groups, thereby providing a non-limiting amino silane. In one embodiment, the precursor has a formula of (R′)₄₋ₓSi(NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″₂N)ₓ(R′)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″₂) attached to one or more silicon atoms.

In some embodiments, R′ is H, optionally substituted amino (e.g., —NR²), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R′ group attached to the silicon atom. In one embodiment, the precursor has a formula of (R′)(H)₃₋ₓSi(NR″₂)ₓ, wherein R′ and R″ can be any described herein, and wherein x is 1, 2, or 3. In another embodiment, the precursor has a formula of (R′)(H)₂Si(NR″₂), wherein R′ and R″ can be any described herein. In one embodiment, the precursor has a formula of (R′)(H)Si(NR″₂)₂, wherein R′ and R″ can be any described herein. In another embodiment, the precursor has a formula of (R′)₂(H)Si(NR″₂), wherein R′ and R″ can be any described herein. In yet another embodiment, the precursor has a formula of (R′)₂Si(NR″₂)₂, wherein R′ and R″ can be any described herein. In one embodiment, the precursor has a formula of (R′)₃Si(NR″₂), wherein R′ and R″ can be any described herein.

The precursor can lack an R′ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂)ₓ, wherein each R″ can independently be any described herein. In particular embodiments, each R″ is, independently, aliphatic, heteroaliphatic, aromatic, or heteroaromatic.

The precursor can include one or more hydrogen atoms attached to the silicon atom. In one embodiment, the precursor has a formula of (H)₃Si(NR″₂) or (H)₂Si(NR″₂)₂ or (H)Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The precursor can include a heterocyclyl group having a nitrogen atom. In one embodiment, the formula has a formula of H₃Si-Het, in which Het is an optionally substituted heterocyclyl including at least one nitrogen atom. In particular embodiments, the precursor has a formula of

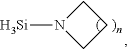

in which the heterocyclyl group can be optionally substituted (e.g., with any substituent described herein as a substitution for alkyl), and wherein n is 1,2, 3, 4, or 5. In one embodiment, the formula has a formula of R′₃Si-Het, in which Het is an optionally substituted heterocyclyl including at least one nitrogen atom, and each R′ can independently be any described herein. In particular embodiments, the precursor has a formula of

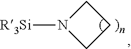

in which the heterocyclyl group can be optionally substituted (e.g., with any substituent described herein as a substitution for alkyl); each R′ can independently be any described herein; and wherein n is 1,2, 3, 4, or 5.

In some instances, the precursor can have two or more silicon atoms, in which the precursor can include a Si—Si bond. In a particular embodiment, the precursor has a formula of (R″₂N)ₓ(R′)₃₋ₓSi—Si(R′)₃₋ₓ(NR″₂)ₓ, wherein R′ and R″ can be any described herein. In one embodiment, the precursor has a formula of (R″₂N)(R′)₂Si—Si(R′)₂(NR″₂), wherein R′ and R″ can be any described herein. In another embodiment, the precursor has a formula of (R″₂N)₂(R′)Si—Si(R′)(NR″₂)₂, wherein R′ and R″ can be any described herein. In yet another embodiment, the precursor has a formula of (R″₂N)₃Si—Si(NR″₂)₃, wherein each R″ can independently be any described herein.

The precursor can include differing groups attached to the silicon atoms. In one instance, the precursor has a formula of (R″₂N)ₓ(R′)₃₋ₓSi—SiH₃, wherein R′ and R″ can be any described herein.

A linker can be present between two silicon atoms. In one instance, the precursor has a formula of (R″₂N)ₓ(R′)₃₋ₓSi—NR—Si(R′)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the precursor has a formula of (R″₂N)ₓ(H)₃₋ₓSi—NR—Si(H)₃₋ₓ(NR″₂)ₓ, wherein R, R′, and R″ can be any described herein.

The precursor can include a combination of R′ groups with a linker having a heteroatom. In one instance, the precursor has a formula of (R′)₃Si—NR—Si(R′)₃, wherein R and R′ can be any described herein. In another instance, the precursor has a formula of (R′)₃Si-L-Si(R′)₃, wherein L and R′ can be any described herein. In particular embodiments, L is oxy (—O—), optionally substituted imino (e.g., —NR—), or optionally substituted silyl (e.g., —SiR₂—).

The precursor can include any useful combination of R′ and NR″₂ groups in combination with two silicon atoms. In one instance, the precursor has a formula of (R″₂N)(R′)₃Si-L-Si(R′)₂(NR″₂)ₓ, wherein L, R′, and R″ can be any described herein.

The precursor can include heterocyclic groups including the silicon and nitrogen atoms. In one embodiment, the precursor has a formula of

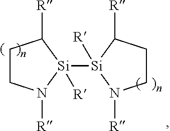

wherein R′ and R″ can be any described herein, and wherein n is 1, 2, 3, or 4.

In another embodiment, the precursor has a formula of

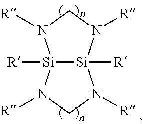

wherein R′ and R″ can be any described herein, and wherein n is 1, 2, 3, or 4. In yet another embodiment, the precursor has a formula of

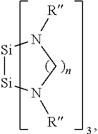

in which each R″ can independently be any described herein; and wherein n is 1,2, 3, or 4.

In another embodiment, the precursor has a formula of

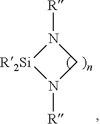

wherein R′ and R″ can be any described herein, and wherein n is 1, 2, 3, or 4. In yet another embodiment, the precursor has a formula of

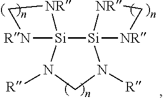

wherein R″ can independently be any described herein, and wherein n is 1, 2, 3, or 4.

In any precursor herein, two R″ can be taken together, with the nitrogen atom to which each is attached, to form an optionally substituted heterocyclyl.

Precursors can include any of the following, e.g., (R^{Ak})Si(NH₂)(NR^{Ak}₂)₂, (R^{Ak})Si(NR^{Ak}₂)₃, (R^{Ak})₂Si(NHR^{Ak}₂)₂, (R^{Ak})(H)Si(NHR^{Ak})₂, (R^{Ak})₃Si(NR^{Ak}₂), (R^{Ak})₃Si(NHR^{Ak}), H₂Si(NHR^{Ak}₂)₂, (R^{Ak})(H)Si(NR^{Ak}₂)₂, HSi(NH₂)(NR^{Ak}₂), HSi(NR^{Ak}₂)₃, Si(NR^{Ak}₂)₄, (R′)(H)Si(NR″₂)₂, (R′)₂Si(NR^{Ak}₂)₂, (R′)₂Si(N[SiH₃]₂)₂, (R′)₂Si(N[SiR″₃]₂)₂, or (R′)₃Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{Ak} is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of precursor include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe₃[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane (SiHEt₂[NEt₂]); diethylaminotrimethylsilane (SiMe₃[NEt₂]); diethylaminotriethylsilane (SiEt₃[NEt₂]); iso-propylaminodimethylsilane (SiHMe₂[NHiPr]); iso-propylaminotrimethylsilane (SiMe₃[NHiPr]); iso-propylaminodiethylsilane (SiHEt₂[NHiPr]); iso-propylaminotriethylsilane (SiEt₃[NHiPr]); di-isopropylaminotrimethylsilane (SiMe₃[NiPr₂]); di-iso-propylaminosilane (SiH₃[NiPr₂], C₆H₁₇NSi, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPr₂]); di-isopropylaminotriethylsilane (SiEt₃[NiPr₂]); n-propylaminotrimethylsilane (SiMe₃[NHnPr]); di-sec-butylaminosilane (SiH₃[NsBu₂] or DSBAS): di-sec-butylaminomethylsilane (SiH₂Me[NsBu₂]); iso-butylaminotrimethylsilane (SiMe₃[NHiBu]); n-butylaminotrimethylsilane (SiMe₃[NHnBu]); tert-butylaminodimethylsilane (SiHMe₂[NHtBu]); tert-butylaminotrimethylsilane (SiMe₃[NHtBu]); tert-butylaminodiethylsilane (SiHEt₂[NHtBu]); tert-butylaminotriethylsilane (SiEt₃[NHtBu]); dicyclohexylaminosilane (SiH₃[NCy₂], in which Cy is cyclohexyl); N-propylisopropylaminosilane (SiH₃[NiPrnPr]); N-methylcyclohexylaminosilane (SiH₃[NMeCy]); N-ethylcyclohexylaminosilane (SiH₃[NEtCy]); allylphenylaminosilane (SiH₃[NAllPh]); N-isopropylcyclohexylaminosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₂[NHPyr], in which Pyr is pyrrolindyl); piperidino trimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidazolyl); bis(dimethylamino)silane (SiH₂[NMe₂]₂ or BDMAS); bis(dimethylamino)methylsilane (SiMeH[NMe₂]₂); bis(dimethylamino)dimethylsilane (SiMe₂[NMe₂]₂ or BDMADMS); bis(dimethylamino) diethylsilane (SiEt₂[NMe₂]₂); bis(dimethylamino)methylvinylsilane (SiMeVi[NMe₂]₂); bis(ethylamino)dimethylsilane (SiMe₂[NHEt]₂); bis(ethylmethylamino)silane (SiH₂[NMeEt]₂); bis(ethylmethylamino)dimethylsilane (SiMe₂[NMeEt]₂); bis(ethylmethylamino) diethylsilane (SiEt₂[NMeEt]₂); bis(ethylmethylamino) methylvinylsilane (SiMeVi[NMeEt]₂); bis(diethylamino)silane (SiH₂[NEt₂]₂, C₈H₂₂N₂Si, or BDEAS); bis(diethylamino)dimethylsilane (SiMe₂[NEt₂]₂); bis(diethylamino)methylvinylsilane (SiMeVi[NEt₂]₂); bis(diethylamino) diethylsilane (SiEt₂[NEt₂]₂); bis(iso-propylamino)dimethylsilane (SiMe₃[NHiPr]₂); bis(iso-propylamino) diethylsilane (SiEt₂[NHiPr]₂); bis(iso-propylamino)methylvinylsilane (SiMeVi[NHiPr]₂); bis(di-iso-propylamino)silane (SiH₂[NiPr₂]₂); bis(di-iso-propylamino)dimethylsilane (SiMe₂[NiPr₂]₂); bis(di-iso-propylamino) diethylsilane (SiEt₂[NiPr₂]₂); bis(di-iso-propylamino)methylvinylsilane (SiMeVi[NiPr₂]₂); bis(methylamino)silane (SiH₂[NHMe]₂); bis(sec-butylamino)silane (SiH₂[NHsBu]₂); bis(sec-butylamino)methylsilane (SiHMe[NHsBu]₂); bis(sec-butylamino)ethylsilane (SiHEt[NHsBu]₂); bis(tert-butylamino)silane (SiH₂[NHtBu]₂ or BTBAS); bis(tert-butylamino)dimethylsilane (SiMe₂[NHtBu]₂); bis(tert-butylamino)methylvinylsilane (SiMeVi[NHtBu]₂); bis(tert-butylamino) diethylsilane (SiEt₂[NHtBu]₂); bis(1-imidazolyl)dimethylsilane (SiMe₂[Im]₂, in which Im is imidazolyl); tris(dimethylamino)silane (SiH[NMe₂]₃ or 3DMAS); tris(dimethylamino)phenylsilane (SiPh[NMe₂]₃); tris(dimethylamino)methylsilane (SiMe[NMe₂]₃); tris(dimethylamino)ethylsilane (SiEt[NMe₂]₃); tris(ethylmethylamino)silane (SiH[NEtMe]₃); tris(diethylamino)silane (SiH[NEt₂]₃); tris(iso-propylamino)silane (SiH[NHiPr]₃, C₉H₂₅N₃Si, or TIPAS); tris(dimethylamino) silylamide (Si[NMe₂]₃[NH₂]); tetrakis(dimethylamino)silane (Si[NMe₂]₄); tetrakis(ethylmethylamino)silane (Si[NEtMe]₄); tetrakis(diethylamino)silane (Si[NEt₂]₄); 1,2-diethyl-tetrakis(diethylamino) disilane ([Et₂N]₂EtSi-SiEt[NEt₂]₂); 1,2-dimethyl-tetrakis(dimethylamino) disilane ([Me₂N]₂MeSi—SiMe[NMe₂]₂); 1,2-dimethyl-tetrakis(diethylamino) disilane ([Et₂N]₂MeSi-SiMe[NEt₂]₂); hexakis(methylamino)disilane ([MeHN]₃Si—Si[NHMe]₃); hexakis (ethylamino)disilane ([EtHN]₃Si—Si[NHEt]₃); hexakis (dimethylamino)disilazane (Me₂N—Si[NMe₂]₂—Si[NMe₂]₂—NMe₂), and the like.

### Isocyanato Silanes

A silicon-containing precursor can include one or more isocyanato groups, thereby providing a non-limiting isocyanato silane. In one embodiment, the precursor has a formula of (R′)₄₋ₓSi(NCO)ₓ, wherein:
x is 1, 2, 3, or 4; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In another embodiment, the precursor has a formula of (R′)_{z}Si(NCO)ₓ(NR″₂)_{y}, wherein:
x is 1, 2, 3, or 4;
each of y and z is, independently, 0, 1, 2, or 3;

$$x + y + z = 4 ;$$

each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In yet another embodiment, the precursor has a formula of (NCO)ₓ(R′)₃₋ₓSi-L-Si(R′)₃₋ₓ(NCO)ₓ, wherein:
each x is, independently, 0, 1, 2, or 3;
L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl; and
each R′ is, independently. H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In some embodiments, R′ is H, optionally substituted amino (e.g., —NR²), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂) c in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

Precursors can include any of the following, e.g., (R′)Si(NCO)(NR″₂)₂, (R′)₂Si(NCO)(NR″₂), (R′)₂Si(NCO)(N[SiR₃]₂), or tetraisocyanatosilane (Si[NCO]₄). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R is, independently, H, optionally substituted aliphatic, optionally substituted heteroaliphatic, optionally substituted alkyl, optionally substituted alkenyl, optionally substituted alkynyl, optionally substituted alkoxy, optionally substituted aromatic, optionally substituted heteroaromatic, optionally substituted aryl, or optionally substituted heteroaryl.

### Azido Silanes

A silicon-containing precursor can include one or more azido groups, thereby providing a non-limiting azido silane. In one embodiment, the precursor has a formula of (R′)₄₋ₓSi(N₃)ₓ, wherein:
x is 1, 2, 3, or 4; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In another embodiment, the precursor has a formula of (R′)_{z}Si(N₃)ₓ(NR″₂)_{y}, wherein:
x is 1, 2, 3, or 4;
each of y and z is, independently, 0, 1, 2, or 3;

$$x + y + z = 4 ;$$

each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In yet another embodiment, the precursor has a formula of (N₃)ₓ(R′)₃₋ₓSi-L-Si(R′)₃₋ₓ(N₃)ₓ, wherein:
each x is, independently, 0, 1, 2, or 3;
L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl; and
each R′ is, independently. H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In some embodiments, R′ is H, optionally substituted amino (e.g., —NR²), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂), —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂) c in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

Precursors can include any of the following, e.g., (R′)₃Si(N₃), (R′)₂Si(N₃)₂, (R′)Si(N₃)₃, or Si(N₃)(NR″₂)₃. In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). Non-limiting examples of precursors also include tris(dimethylamino)silylazide ([Me₂N]₃SiN₃); di-tert-butyl diazidosilane (tBu₂Si(N₃)₂); ethylsilicon triazide (EtSi(N₃)₃); and the like.

### Hydrazino Silanes

A silicon-containing precursor can include one or more optionally substituted hydrazino groups, thereby providing a non-limiting hydrazino silane. In one embodiment, the precursor has a formula of (R′)₄₋ₓSi(NR″—NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (NR″₂—NR″)ₓ(R′)₃₋ₓSi-L-Si(R′)₃₋ₓ(NR″—NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In yet another embodiment, the precursor has a formula of (R′)₄₋ₓSi(NR″-L-NR″₂)ₓ, wherein: x is 1, 2, 3, or 4; and each L, R′, and R″ can be any described herein.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic. In yet other embodiments, L is —NR—NR—, in which R is any described herein (e.g., R is H, optionally substituted aliphatic, optionally substituted alkyl, optionally substituted alkenyl, optionally substituted alkynyl, or optionally substituted aromatic).

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

The precursor can include any useful combination of R′ and hydrazino groups. In one embodiment, the precursor has a formula of (R′)₃Si(NR″-L-NR″₂) or (R′)₃Si(NR″—NR″₂), wherein L, R′, and R″ can be any described herein.

The precursor can include a plurality of hydrazino groups. In one embodiment, the precursor has a formula of (R′)₂Si(NR″-L-NR″₂)₂, (R′)₂Si(NR″—NR″₂)₂, or (R′)₃Si(NH—NHR″)₂, wherein L, R′, and R″ can be any described herein.

The precursor can include at least two silicon atoms. In one embodiment, the precursor has a formula of (NR″₂—NR″)(R′)₂Si—Si(R′)₂(NR″—NR″₂), wherein each R′ and R″ can be any described herein.

Non-limiting precursors can include bis(tert-butylhydrazino) diethylsilane (SiEt₂[NH—NHtBu]₂); tris(dimethylhydrazino)silane (SiH[NH—NMe₂]₃); and the like.

### Siloxanes and Derivatives Thereof

A silicon-containing precursor can include one or more aliphatic-oxy, aromatic-oxy groups, and/or oxy groups, thereby providing a siloxane or a derivative thereof having one or more Si—O, O—Si—O, or Si—O—Si bonds. In one embodiment, the precursor has a formula of (R′)₄₋ₓSi(OR″)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, silyl, or silyloxy, in which any of these may be optionally substituted.

In another embodiment, the precursor has a formula of (R″O)ₓ(R′)₃₋ₓSi-L-Si(R′)₃₋ₓ(OR″)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, silyl, or silyloxy, in which any of these may be optionally substituted.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic. In other embodiments, L is —O-L′—O—, in which L′ is optionally substituted aliphatic, optionally substituted heteroaliphatic, optionally substituted aromatic, optionally substituted heteroaromatic, optionally substituted silyl (e.g., —SiR₂—), optionally substituted alkylene (e.g., —(CH₂)ₙ—, in which n is 1 to 6), optionally substituted arylene, and the like. In yet other embodiments, L is oxy.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In some embodiments, R′ is H, optionally substituted amino (e.g., —NR²), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include one or more hydrogen atoms attached to the silicon atom. In one embodiment, the precursor has a formula of H₃Si(OR″), H₂Si(OR″)₂, or HSi(OR″)₃, wherein each R″ can independently be any described herein.

The precursor can include any combination of R′ and OR″ groups within the precursor. In one embodiment, the precursor has a formula of (R′)₃Si(OR″), (R′)₂Si(OR″)₂, or (R′)Si(OR″)₃, wherein each of R′ and R″ can independently be any described herein. The precursor can include alkyl groups, such as in the precursor having a formula of (R^{Ak})₃Si(OR^{Ak}), (R^{Ak})₂Si(OR^{Ak})₂, or (R^{Ak})Si(OR^{Ak})₃, in which R^{Ak} is optionally substituted alkyl.

In some instances, the precursor can have two or more silicon atoms, in which the precursor can include a Si—Si bond. In a particular embodiment, the precursor has a formula of (R″O)ₓ(R′)₃₋ₓSi—Si(R′)₃₋ₓ(OR″)ₓ, wherein R′ and R″ can be any described herein. In one embodiment, the precursor has a formula of (R″O)(R′)₃Si—Si(R′)₂(OR″), wherein R′ and R″ can be any described herein.

The precursor can include a combination of R′ groups with a linker having a heteroatom. In one instance, the precursor has a formula of (R′)₃Si—O—Si(R′)₃, wherein R′ can be any described herein. In another instance, the precursor has a formula of (R′)₃Si—O-L′—O—Si(R′)₃, wherein L′ and R′ can be any described herein. In yet another instance, the precursor has a formula of (R′)₃Si—(OSiR′₂)_{z}—R′, wherein R′ can be any described herein; and in which z is 1, 2, 3, 4, or more. In another instance, the precursor has a formula of (R′)₄₋ₓSi—[(OSiR′₂)_{z}—R′]ₓ, wherein R′ can be any described herein; x is 1, 2, 3, or 4; and z is 1, 2, 3, 4, or more.

The precursor can include any useful combination of R′ and OR″ groups in combination with two silicon atoms. In one instance, the precursor has a formula of (R″O)ₓ(R′)₃₋ₓSi—O—Si(R′)₃₋ₓ(OR″)ₓ, wherein R′ and R″ can be any described herein. In another instance, the precursor has a formula of (R″O)ₓ(R′)₃₋ₓSi—O-L′—O—Si(R′)₃₋ₓ(OR″)ₓ, wherein L′, R′, and R″ can be any described herein.

Non-limiting precursors can include methoxydimethylsilane (SiHMe₂[OMe]); ethoxydimethylsilane (SiHMe₂[OEt]); iso-propoxydimethylsilane (SiHMe₂[OiPr]); t-butoxydimethylsilane (SiHMe₂[OtBu]); t-pentoxydimethylsilane (SiHMe₂[OtPe]); phenoxy dimethylsilane (SiHMe₂[OPh]); acetoxydimethylsilane (SiHMe₂[OAc]); methoxytrimethylsilane (SiMe₃[OMe]); ethoxytrimethylsilane (SiMe₃[OEt]); iso-propoxytrimethylsilane (SiMe₂[OiPr]); t-butoxytrimethylsilane (SiMe₃[OtBu]); t-pentoxytrimethylsilane (SiMe₃[OtPe]); phenoxy trimethylsilane (SiMe₃[OPh]); acetoxytrimethylsilane (SiMe₃[OAc]); methoxytriethylsilane (SiEt₃[OMe]); ethoxytriethylsilane (SiEt₃[OEt]); iso-propoxytriethylsilane (SiEt₃[OiPr]); t-butoxytriethylsilane (SiEt₃[OtBu]); t-pentoxytriethylsilane (SiEt₃[OtPe]); phenoxytriethylsilane (SiEt₃[OPh]); acetoxytriethylsilane (SiEt₃[OAc]); dimethoxysilane (SiH₂[OMe]₂); diethoxysilane (SiH₂[OEt]₂); di-iso-propoxysilane (SiH₂[OPr]₂); di-tert-butoxysilane (SiH₂[OtBu]₂ or DTBOS); di-tert-pentoxysilane (SiH₂[OtPe]₂ or DTPOS); diacetoxysilane (SiH₂[OAc]₂); dimethoxy dimethylsilane (SiMe₂[OMe]₂); diethoxydimethylsilane (SiMe₂[OEt]₂); di-iso-propoxy dimethylsilane (SiMe₂[OPr]₂); di-tert-butoxydimethylsilane (SiMe₂[OtBu]₂); diacetoxy dimethylsilane (SiMe₂[OAc]₂); dimethoxydiethylsilane (SiEt₂[OMe]₂); diethoxydiethylsilane (SiEt₂[OEt]₂); di-iso-propoxydiethylsilane (SiEt₂[OiPr]₂); di-tert-butoxydiethylsilane (SiEt₂[OtBu]₂); diacetoxydiethylsilane (SiEt₂[OAc]₂); dimethoxydiphenylsilane (SiPh₂[OMe]₂); dimethoxydi-iso-propylsilane (Si[iPr]₂[OMe]₂); diethoxydi-iso-propylsilane (Si[iPr]₂[OEt]₂); di-iso-propoxydi-iso-propylsilane (Si[iPr]₂[OiPr]₂); di-tert-butoxydi-iso-propylsilane (Si[iPr]₂[OtBu]₂); diacetoxydi-iso-propylsilane (Si[iPr]₂[OAc]₂); dimethoxymethylvinylsilane (SiMeVi[OMe]₂); diethoxymethylvinylsilane (SiMeVi[OEt]₂); di-iso-propoxymethylvinylsilane (SiMeVi[OiPr]₂); di-tert-butoxymethylvinylsilane (SiMeVi[OtBu]₂); diacetoxymethylvinylsilane (SiMeVi[OAc]₂); triethoxysilane (SiH[OEt]₃ or TES); trimethoxyethylsilane (SiEt[OMe]₃); triethoxymethylsilane (SiMe[OEt]₃); triethoxyphenylsilane (SiPh[OEt]₃); tetramethoxysilane (Si[OMe]₄); tetraethoxysilane (Si[OEt]₄ or TEOS); tetra-n-propoxysilane (Si[OnPr]₄); tetra-iso-propoxysilane (Si[OiPr]₄): tetra-n-butoxysilane (Si[OnBu]₄); tetra-t-butoxysilane (Si[OtBu]₄); tetramethyldisiloxane (O[SiHMe₂]₂ or TMDO); hexamethyldisiloxane (O[SiMe₃]₂); hexaethyldisiloxane (O[SiEt₃]₂); hexapropyldisiloxane (O[SiPr₃]₂); hexaphenyldisiloxane (O[SiPh₃]₂); hexamethyltrisiloxane (Me₂SiH—O—SiMe₂-O—SiHMe₂); and the like.

### Mixed Silanes Including Oxygen and Nitrogen

A silicon-containing precursor can include one or more optionally substituted amino groups with either aliphatic-oxy or aromatic-oxy groups, thereby providing a non-limiting mixed silane. In one embodiment, the precursor has a formula of (R′)_{z}Si(OR″)ₓ(NR″₂)_{y}, wherein:
each of x and y is, independently, 1, 2, 3, or 4;
z is 0, 1, or 2;

$$x + y + z = 4 ;$$

each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″ is, independently, H, aliphatic, heteroaliphatic, aromatic, heteroaromatic, silyl, or silyloxy, in which any of these may be optionally substituted.

In another embodiment, the precursor has a formula of (R″₂N)_{y}(R″O)ₓ(R′)₂Si-L-Si(R′)_{z}(OR″)ₓ(NR″₂)_{y}, wherein:
each of x and y is more than 0 (e.g., 1 or 2);
z is 0 or 1;

$$x + y + z = 3 ;$$

L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″ is, independently, H, aliphatic, heteroaliphatic, aromatic, heteroaromatic, silyl, or silyloxy, in which any of these may be optionally substituted.

Non-limiting examples of R′, R″, and R″ are described herein, e.g., such as for amino silane, siloxane, or derivatives thereof.

The precursor can include any combination of R′, NR″₂, and OR″ groups. In one embodiment, the precursor has a formula of (R′)Si(OR″)₂(NR″₂) or (R′)₃Si(OR″)₂(NR″₂), wherein each of R′, R″, and R″ can independently be any described herein. In other embodiments, the precursor has a formula of (R′)₂Si(OR″)(N[SiR₃]₂), wherein each of R′ and R″ can independently be any described herein; and R is, independently, H, optionally substituted aliphatic, optionally substituted heteroaliphatic, optionally substituted aromatic, or optionally substituted heteroaromatic.

The precursor can include only amino and oxy-containing groups attached to the silicon atom. In one embodiment, the precursor has a formula of Si(OR″)₃ (NR″₂), Si(OR″)₂(NR″₂)₂, or Si(OR″)(NR″₂)₃, wherein each of R″ and R″ can independently be any described herein. Non-limiting precursors can include, e.g., diethoxy (iso-propylamino)silane (SiH[NHiPr][OEt]₂); diethoxy (tert-butylamino)silane (SiH[NHtBu][OEt]₂); diethoxy (tert-pentylamino)silane (SiH[NHtPe][OEt]₂); di-tert-butoxy(methylamino)silane (SiH[NHMe][OtBu]₂); di-tert-butoxy (ethylamino)silane (SiH[NHEt][OtBu]₂); di-tert-butoxy (iso-propylamino)silane (SiH[NHiPr][OtBu]₂); di-tert-butoxy (n-butylamino)silane (SiH[NHnBu][OtBu]₂); di-tert-butoxy (sec-butylamino)silane (SiH[NHsBu][OtBu]₂); di-tert-butoxy (iso-butylamino)silane (SiH[NHiBu][OtBu]₂); di-tert-butoxy (tert-butylamino)silane (SiH[NHtBu][OtBu]₂); di-tert-pentoxy(methylamino)silane (SiH[NHMe][OtPe]₂); di-tert-pentoxy (ethylamino)silane (SiH[NHEt][OtPe]₂); di-tert-pentoxy (iso-propylamino)silane (SiH[NHiPr][OtPe]₂); di-tert-pentoxy (n-butylamino)silane (SiH[NHnBu][OtPe]₂); di-tert-pentoxy (sec-butylamino)silane (SiH[NHsBu][OtPe]₂); di-tert-pentoxy (iso-butylamino)silane (SiH[NHiBu][OtPe]₂); di-tert-pentoxy (tert-butylamino)silane (SiH[NHtBu][OtPe]₂); dimethoxy (phenylmethylamino)silane (SiH[NPhMe][OMe]₂); diethoxy (phenylmethylamino)silane (SiH[NPhMe][OEt]₂); dimethoxy (phenylmethylamino)methylsilane (SiMe[NPhMe][OMe]₂); diethoxy (phenylmethylamino)methylsilane (SiEt[NPhMe][OEt]₂); and the like.

### Silyl Amines

A silicon-containing precursor can include one or more optionally substituted silyl groups attached to a nitrogen atom, thereby providing a non-limiting silyl amine. In one embodiment, the precursor has a formula of (R″)_{3-y}N(SiR′₃)_{y}, wherein:
y is 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the precursor has a formula of (R′₃Si)_{y}(R″)_{2-y}N-L-N(R″)_{2-y}(SiR′₃)_{y}, wherein:
each y is, independently, 0, 1, or 2;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl, optionally in which N-L-N, taken together, forms a multivalent heterocyclyl group.

In one instance, at least one y is not 0. In another embodiment, y can be 0 (e.g., if L includes a carbon atom or a heteroatom). In yet another embodiment, y is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In some embodiments, R′ is H, optionally substituted amino (e.g., —NR²), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃ or —SiR₂-L-SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl. L can be any useful linker (e.g., a covalent bond, optionally substituted alkylene, optionally substituted heteroalkylene, oxy, imino, silyl, or the like).

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R″ group attached to the nitrogen atom. In one embodiment, the precursor has a formula of (R″)N(SiR′₃)₂ or (R″)₂N(SiR′₃), wherein R′ and R″ can be any described herein. In another embodiment, the precursor has a formula of (R″)₂N(SiH₃) or (R″)N(SiH₃)₂, wherein R″ can be any described herein. In particular embodiments, R′ is optionally substituted alkyl, amino, or alkoxy; and R″ is optionally substituted alkyl or amino, optionally wherein two R″ are taken together, with the nitrogen atom to which each are attached, to form a heterocyclyl.

The precursor can include at least one hydrogen atom attached to the nitrogen atom. In one embodiment, the precursor has a formula of (H)N(SiR′₃)₂, wherein R′ can be any described herein. In another embodiment, the precursor has a formula of (H)N(SiR^{Ak}₃)₂, wherein R^{Ak} can be optionally substituted aliphatic, optionally substituted alkyl, optionally substituted alkenyl, or optionally substituted alkynyl.

The precursor can include three silicon atoms attached to the nitrogen atom. In one embodiment, the precursor has a formula of N(SiR′₃)₃, wherein R′ can be any described herein. In another embodiment, the precursor has a formula of N(SiH₃)(SiR′₃)₂, wherein R′ can be any described herein. In yet another embodiment, the precursor has a formula of N(SiH₃)(SiR^{Ak}₃)₂, wherein R^{Ak} can be optionally substituted aliphatic, optionally substituted alkyl, optionally substituted alkenyl, or optionally substituted alkynyl.

The precursor can have two or more nitrogen atoms, in which the precursor includes a N—N bond. In one instance, the precursor has a formula of (R′₃Si)₂N—N(SiR′₃)₂, wherein R′ can be any described herein.

A linker can be present between nitrogen atoms. In one instance, the precursor has a formula of (R′₃Si)(R″)N-L-N(R″)(SiR′₃) or (R′₃Si)₂N-L-N(SiR′₃)₂, wherein R′ and R″ can be any described herein. In some embodiments, L is a covalent bond, optionally substituted alkylene, optionally substituted heteroalkylene, —O—, —SiR₂—, or —Si—. In particular embodiments, at least one of R″ is not H. In another instance, the precursor has a formula of (H₃Si)(R″)N-L-N(R″)(SiH₃), wherein R″ can be any described herein.

The linker can include a silicon atom. In one instance, the precursor has a formula of (R′₃Si)₂N—SiR′₂—N(SiR′₃)₂, wherein R′ can be any described herein. In another instance, the precursor has a formula of (R′₃Si)(R″)N—SiR′₂—N(R″)(SiR′₃) or (R′₃Si)₂N—SiR′₂—N(R″)₂, wherein R′ and R″ can be any described herein.

The linker can include a SiH₂ group. In one instance, the precursor has a formula of (R′₃Si)₂N—SiH₂—N(SiR′₃)₂, wherein R′ can be any described herein. In another instance, the precursor has a formula of (R′₃Si)HN—SiH₂—NH(SiR′₃) or (R′₃Si)₂N—SiH₂—N(R″)₂, wherein R′ and R″ can be any described herein.

A plurality of nitrogen- and silicon-containing moieties may be present within the precursor. In one embodiment, the precursor has a formula of (R′₃Si)(R″)N—SiR′₂—N(R″)—SiR′₂—N(R″)(SiR′₃), wherein R′ and R″ can be any described herein.

Non-limiting precursors can include, e.g., 1,1,3,3-tetramethyldisilazane (NH[SiHMe₂]₂ or TMDS); 1,1,2,3,3-pentamethyldisilazane (NMe[SiHMe₂]₂); 1,1,1,3,3,3-hexamethyldisilazane (NH[SiMe₃]₂ or HMDS); heptamethyldisilazane (NMe[SiMe₃]₂); 1,1,1,3,3,3-hexamethyl-2-ethyldisilazane (NEt[SiMe₃]₂); 1,1,1,3,3,3-hexamethyl-2-isopropyldisilazane (NiPr[SiMe₃]₂); 1,1,1,3,3,3-hexaethyl-2-isopropyldisilazane (NiPr[SiEt₃]₂); 1,1,3,3-tetramethyl-2-isopropyl disilazane (NiPr[SiHMe₂]₂); 1,1,3,3-tetraethyl-2-isopropyldisilazane (NiPr[SiHEt₂]₂); 1,3-diethyltetramethyldisilazane (NH[SiMe₂Et]₂); 1,1,3,3-tetraethyldisilazane (NH[SiHEt₂]₂): 1,1,3,3-tetraethyl-2-methyldisilazane (NMe[SiHEt₂]₂); 1,1,1,3,3,3-hexaethyldisilazane (NH[SiEt₃]₂); 1,1,1,3,3,3-hexaethyl-2-methyldisilazane (NMe[SiEt₃]₂); 1,1,1,2,3,3,3-heptaethyldisilazane (NEt[SiEt₃]₂); 1,2,3-trimethyltrisilazane (N[SiH₂Me]₃); nonamethyltrisilazane (N[SiMe₃]₃); di-iso-propylsilylamine (NiPr₂[SiH₃]); diethylsilylamine (NEt₂[SiH₃]); diisopropylsilylamine (NiPr₂[SiH₃]); di-sec-butylsilylamine (NsBu₂[SiH₃]); di-tert-butylsilylamine (NtBu₂[SiH₃]); disilylmethylamine (NMe[SiH₃]₂); disilylethylamine (NEt[SiH₃]₂); disilylisopropylamine (NiPr[SiH₃]₂); disilyl-tert-butylamine (NtBu[SiH₃]₂); bis(trimethylsilyl)amine (NH[SiMe₃]₂); bis(triethylsilyl)amine (NH[SiEt₃]₂); and the like.

### Silazanes and Derivatives Thereof

A silicon-containing precursor can include one or more amino, silyl, and/or imino groups, thereby providing a silazane or a derivative thereof having one or more Si—N, N—Si—N, Si—N—Si, N—Si—Si, or N—Si—N—Si bonds. In one embodiment, the precursor has a formula of (R″)_{3-y}N(SiR′₂-L-SiR′₃)_{y}, wherein:
y is 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the precursor has a formula of (R″)_{3-y}N(SiR′₂-L-SiR′₂—NR″₂)_{y}, wherein y is 1, 2, or 3; and each of L, R′, and R″ can be any described herein.

In yet another embodiment, the precursor has a formula of (R″)_{3-y}N(SiR′₂-L-NR″₂)_{y}, wherein y is 1, 2, or 3; and each of L, R′, and R″ can be any described herein.

In one embodiment, the precursor has a formula of (R′)₄₋ₓSi(NR″-L-SiR′₃)ₓ, wherein:
x is 1, 2, 3, or 4;
L is a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the precursor has a formula of (R″₂N)—(SiR′₂-L)_{z}-SiR′₃, wherein z is 1, 2, or 3; and each of L, R′, and R″ can be any described herein.

In some embodiments, L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In some embodiments, R′ is H, optionally substituted amino (e.g., —NR²), aliphatic-oxy (e.g., alkoxy or —OR), aliphatic-carbonyl (e.g., alkanoyl or —C(O)) R), aliphatic-carbonyloxy (e.g., alkanoyloxy or —OC(O)R), aliphatic-oxycarbonyl (e.g., alkoxycarbonyl or —C(O)OR), silyl (e.g., —SiR₃ or —SiR₂-L-SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl. L can be any useful linker (e.g., a covalent bond, optionally substituted alkylene, optionally substituted heteroalkylene, oxy, imino, silyl, or the like).

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂) c in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include one or more disilanyl groups and amino groups. In one embodiment, the precursor has a formula of R″₂N—SiR′₂—SiR′₃, wherein L, R′, and R″ can be any described herein. In other embodiments, the precursor has a formula of R″₂N—SiH₂—SiH₃, wherein R″ is any described herein. In another embodiment, the precursor has a formula of (R″)_{3-y}N—(SiR′₂—SiR′₃)_{y}, wherein y, R′, and R″ can be any described herein. In yet another embodiment, the precursor has a formula of (R″)_{3-y}N—(SiH₂—SiH₃)_{y}, wherein y and R″ can be any described herein.

The precursor can include a bivalent disilanyl group. In one embodiment, the precursor has a formula of R″₂N—SiR′₂—SiR′₂-L-NR″₂, wherein L, R′, and R″ can be any described herein. In another embodiment, the precursor has a formula of R″₂N—SiR′₂—SiR′₂—NR″₂, wherein R′ and R″ can be any described herein.

A linker L can be present between two silyl group. In one embodiment, the precursor has a formula of R″₂N—SiR′₂-L-SiR′₃ or R″N—(SiR′₂-L-SiR′₃)₂, wherein L, R′, and R″ can be any described herein. In another embodiment, the precursor has a formula of R″₂N—SiR′₂-L-SiR′₂—NR″₂, wherein L, R′, and R″ can be any described herein. In yet another embodiment, the precursor has a formula of (R″)_{3-y}N—(SiR′₂-L-SiH₃)_{y}, wherein y, L, R′, and R″ can be any described herein.

The precursor can include —SiH₃ as the silyl group. In one embodiment, the precursor has a formula of R″₂N—SiH₂—SiH₃, wherein R″ can be any described herein. In another embodiment, the precursor has a formula of (R″)N—(SiH₂-L-SiH₃)₂ or (R″)₂N—(SiH₂-L-SiH₃), wherein L and R″ can be any described herein.

The precursor can include a silyl-substituted amino group, such as, e.g., —NR″—SiR′₃, in which R′ and R″ can be any described herein. In one embodiment, the precursor has a formula of (R′)₄₋ₓSi(NR″—SiR′₃)ₓ or (R′)₄₋ₓSi(NH—SiR′₃)ₓ, wherein x is 1, 2, 3, or 4; and in which R′ and R″ can be any described herein. In another embodiment, the precursor has a formula of H₂Si(NR″—SiR′₃)₃, wherein R′ and R″ can be any described herein.

The precursor can include a bis-trisilylamino group, such as, e.g., —N(SiR′₃)₂ in which R′ can be any described herein. In one embodiment, the precursor has a formula of R″₂N—SiR′₂—N(SiR′₃)₂, in which R′ and R″ can be any described herein. In another embodiment, the precursor has a formula of R″₂N—SiH₂—N(SiH₃)₂, in which R′ can be any described herein. In yet another embodiment, the precursor has a formula of (R′₃Si)₂N—[SiR′₂—N(SiR′₃)]_{z} (SiR′₃), wherein z is 0, 1, 2, or 3; and in which R′ and R″ can be any described herein.

The precursor can include a linker L disposed between a silicon atom and a nitrogen atom. In one embodiment, the precursor has a formula of R″₂N—SiR′₂-L-NR″₂, wherein L, R′, and R″ can be any described herein.

The precursor can include a linker L disposed between two nitrogen atoms. In one embodiment, the precursor has a formula of R′₃Si—SiR′₂—NR″-L-NR″—SiR′₂—SiR′₃, wherein L, R′, and R″ can be any described herein.

The linker can include a silylimino group, such as, e.g., —N(SiR′₃)—, in which R′ can be any described herein. In one embodiment, the precursor has a formula of R″₂N—[SiR′₂—N(SiR′₃)]_{z}—SiR′₃ or R″₂N—[N(SiR′₃)]_{z}—SiR′₃, in which z is 1, 2, 3, or more; and wherein R′ and R″ can be any described herein.

The linker can include both a silyl group and an imino group. In one embodiment, the precursor has a formula of R″₂N—[SiR′₂—NR″]_{z}—SiR′₃, in which z is 1, 2, 3, or more; and wherein R′ and R″ can be any described herein.

Non-limiting precursors include, e.g., di-iso-propylaminodisilane ([iPr₂N]—SiH₂—SiH₃); di-sec-butylaminodisilane ([sBu₂N]—SiH₂—SiH₃); methylcyclohexylaminodisilane ([MeCyN]—SiH₂—SiH₃); methylphenylaminodisilane ([MePhN]—SiH₂—SiH₃); piperidinodisilane; 3,5-dimethylpiperidinodisilane; di-iso-propylaminotrisilylamine ([iPr₂N]—SiH₂—N[SiH₃]₂); diethyl aminotrisilylamine ([Et₂N]—SiH₂—N[SiH₃]₂); iso-propylaminotrisilylamine ([iPrHN]—SiH₂—N[SiH₃]₂); and the like.

### Mixed Amines Including Silicon and Oxygen

A silicon-containing precursor can include one or more amino groups substituted with a silyl group, thereby providing a non-limiting mixed amine. In one embodiment, the precursor has a formula of (R″)₃—N[Si(OR″)ₓR′₃₋ₓ]_{y}, wherein:
each of x and y is, independently, 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″ is, independently, H, aliphatic, heteroaliphatic, aromatic, heteroaromatic, silyl, or silyloxy, in which any of these may be optionally substituted.

Non-limiting examples of R′, R″, and R″ are described herein, e.g., such as for amino silane, siloxane, silyl amine, or derivatives thereof.

The precursor can include any combination of R″ groups and silicon-containing groups. In one embodiment, the precursor has a formula of (R″)_{3-y}N[Si(OR^{Ak})ₓR^{Ak}₃₋ₓ]_{y} or (R^{Ak})_{3-y}N [Si(OR^{Ak})ₓR^{Ak}₃₋ₓ]_{y}, in which R″, x, and y is any described herein; and wherein R^{Ak} is H, optionally substituted aliphatic, or optionally substituted heteroaliphatic. In particular embodiments, R^{Ak} is H, optionally substituted alkyl, optionally substituted alkylene, or optionally substituted alkynyl. In other embodiments, the precursor has a formula of (R″)_{3-y}N[Si(OR^{Ak})ₓH₃₋ₓ]_{y} or (R″)_{3-y}N[Si(OR^{Ak})H(R^{Ak})]_{y}, in which R″, R^{Ak}, x, and y is any described herein.

The precursor can include two silicon-containing groups. In one embodiment, the precursor has a formula of (R″)N[Si(OR^{Ak})ₓR^{Ak}₃₋ₓ]₂ or (R^{Ak})N[Si(OR^{Ak})ₓR^{Ak}₃₋ₓ]₂, in which R″, R^{Ak}, x, and y is any described herein. In particular embodiments, x is 1 or 2.

The precursor can include a hydrogen atom attached to the nitrogen atom. In one embodiment, the precursor has a formula of (H)_{3-y}N[Si(OR^{Ak})ₓR^{Ak}₃₋ₓ]_{y} or (H)_{3-y}N[Si(OR^{Ak})ₓH₃₋ₓ]_{y} or (H)_{3-y}N[Si(OR^{Ak})H(R^{Ak})]_{y}, in which R^{Ak}, x, and y is any described herein. In particular embodiments, x is 1 or 2.

Non-limiting precursors include, e.g., bis(dimethoxysilyl)amine (NH[Si(OMe)₂H]₂); bis(diethoxysilyl)amine (NH[Si(OEt)₂H]₂); N-iso-propylbis(diethoxysilyl)amine (NiPr[Si(OEt)₂H]₂); bis(methoxymethylsilyl)amine (NH[Si(OMe)MeH]₂); tris(dimethoxysilyl) amine (N[Si(OMe)₂H]₃); tris(methoxymethylsilyl)amine (N[Si(OMe)MeH]₃); tris(diethoxysilyl) amine (N[Si(OEt)₂H]₃); tris(trimethoxysilyl)amine (N[Si(OMe)₃]₃); and the like.

### Cyclic Silazanes

A silicon-containing precursor can include a cyclic group having one or more nitrogen atoms. In one embodiment, the precursor has a formula of [NR″—(SiR′₂)ₙ]_{z}, wherein:
z is 1, 2, 3, 4, 5, or more;
n is 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In one embodiment, the precursor has a formula of [NR″—(SiR′₂) n-L-(SiR′₂)ₙ]_{z}, wherein:
z is 1, 2, 3, 4, 5, or more;
each n is, independently, 1, 2, or 3;
each L is, independently, a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the precursor has a formula of [NR″-L-NR″—(SiR′₂)ₙ]_{z}, wherein: z is 1, 2, 3, 4, 5, or more; each n is, independently, 1, 2, or 3; and in which R′ and R″ can be any described herein.

In yet another embodiment, the precursor has a formula of [L-(SiR′₂)ₙ]_{z}, wherein: z is 1, 2, 3, 4, 5, or more; each n is, independently, 1, 2, or 3; L is imino (e.g., —NR—), optionally substituted aliphatic, optionally substituted heteroaliphatic, or combinations thereof; and in which R′ can be any described herein. In particular embodiments, if L does not include a heteroatom, then R′ includes one or more heteroatoms (e.g., nitrogen atoms).

In one embodiment, the precursor has a formula of

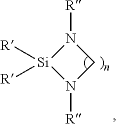

wherein R′ and R″ can be any described herein, and wherein n is 1, 2, 3, or 4.

In another embodiment, the precursor has a formula of

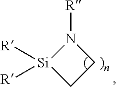

wherein R′ and R″ can be any described herein, and wherein n is 1, 2, 3, or 4.

In yet another embodiment, the precursor has a formula of

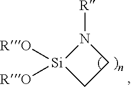

wherein R″ and R″ can be any described herein, and wherein n is 1, 2, 3, or 4. In particular embodiments, each R″ is, independently, H, aliphatic, heteroaliphatic, aromatic, heteroaromatic, silyl, or silyloxy, in which any of these may be optionally substituted.

In one embodiment, the precursor has a formula of

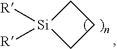

wherein R′ can include a heteroatom (e.g., a nitrogen atom, such as in optionally substituted amino, azido, isocyanato, or optionally substituted hydrazino), and wherein n is 1, 2, 3, or 4.

In some embodiments, L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In other embodiments, L is an optionally substituted alkylene, and at least one R′ includes an optionally substituted heteroaliphatic, optionally substituted amino, optionally substituted aliphatic-oxy, or optionally substituted alkoxy.

In some embodiments, each R′ is, independently, H, optionally substituted aliphatic, optionally substituted alkyl, optionally substituted alkenyl, optionally substituted alkynyl, optionally substituted aromatic, or optionally substituted aryl. In other embodiments, each R′ is, independently, optionally substituted heteroaliphatic, optionally substituted amino, or optionally substituted alkoxy.

In other embodiments, each R″ is, independently, H, optionally substituted aliphatic, optionally substituted alkyl, optionally substituted alkenyl, optionally substituted alkynyl, optionally substituted silyl, optionally substituted amino, optionally substituted aromatic, optionally substituted aryl, optionally substituted heteroaromatic, or optionally substituted heteroaryl.

Non-limiting precursors include 1,3,3-trimethylcyclodisilazane ([NH—SiMe₂][NH—SiMeH]); hexamethylcyclotrisilazane ([NH—SiMe₂]₃); octamethylcyclotetrasilazane ([NH—SiMe₂]₄); and the like.

### Cyclic Siloxanes

A silicon-containing precursor can include a cyclic group having one or more oxygen atoms. In one embodiment, the precursor has a formula of [L-(SiR′₂)ₙ]_{z}, wherein:
is 1, 2, 3, 4, 5, or more;
n is 1, 2, or 3;
L is an oxygen-containing linker (e.g., oxy or heteroalkylene); and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In one embodiment, the precursor has a formula of [O-L′-O—(SiR′₂)ₙ]_{z}, wherein:
z is 1, 2, 3, 4, 5, or more;
n is 1, 2, or 3;
each L′ is, independently, a linker, such as optionally substituted aliphatic, optionally substituted heteroaliphatic, optionally substituted aromatic, optionally substituted heteroaromatic, optionally substituted silyl (e.g., —SiR₂—), optionally substituted alkylene (e.g., —(CH₂)ₙ—, in which n is 1 to 6), and optionally substituted arylene; and
   in which R′ is any described herein.

In another embodiment, the precursor has a formula of [O—(SiR′₂)ₙ-L-(SiR′₂)ₙ]_{z}, wherein:
z is 1, 2, 3, 4, 5, or more;
each n is, independently, 1, 2, or 3;
each L is, independently, a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof; and
   in which R′ is any described herein.

In yet another embodiment, the precursor has a formula of [L-(SiR′₂)ₙ]_{z}, wherein:
is 1, 2, 3, 4, 5, or more; each n is, independently, 1, 2, or 3; L is oxy (—O—), optionally substituted aliphatic, optionally substituted heteroaliphatic, or combinations thereof; and in which R′ can be any described herein. In particular embodiments, if L does not include a heteroatom, then R′ includes one or more heteroatoms (e.g., oxygen atoms).

In one embodiment, the precursor has a formula of

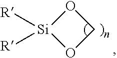

wherein R′ can be any described herein, and wherein n is 1, 2, 3, or 4.

In another embodiment, the precursor has a formula of

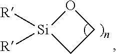

wherein R′ and R″ can be any described herein, and wherein n is 1, 2, 3, or 4.

In yet another embodiment, the precursor has a formula of

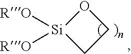

wherein R″ can be any described herein, and wherein n is 1, 2, 3, or 4. In particular embodiments, each R″ is, independently, H, aliphatic, heteroaliphatic, aromatic, heteroaromatic, silyl, or silyloxy, in which any of these may be optionally substituted.

In one embodiment, the precursor has a formula of

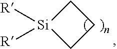

wherein R′ can include a heteroatom (e.g., an oxygen atom, such as in optionally substituted aliphatic-oxy, aliphatic-oxycarbonyl, aliphatic-carbonyl, aliphatic-carbonyloxy, optionally substituted alkoxy, optionally substituted alkoxycarbonyl, optionally substituted alkanoyl, optionally substituted alkanoyloxy, and the like), and wherein n is 1, 2, 3, or 4.

In some embodiments, each R′ is, independently, H, optionally substituted aliphatic, optionally substituted alkyl, optionally substituted alkenyl, optionally substituted alkynyl, optionally substituted aminoalkyl, optionally substituted aromatic, or optionally substituted aryl. In other embodiments, each R′ is, independently, optionally substituted heteroaliphatic, optionally substituted amino, or optionally substituted alkoxy.

Non-limiting precursors include, e.g., tetramethylcyclotetrasiloxane ([OSiHMe]₄ or TMCTS); hexamethylcyclotetrasiloxane ([OSiMe₂OSiHMe]₂ or HMCTS); octamethyl cyclotetrasiloxane ([OSiMe₂]₄, C₈H₂₄O₄Si₄, or OMCTS); decamethylcyclopentasiloxane ([OSiMe₂]₅ or C₁₀H₃₀O₅Si₅); 2-dimethylamino-2,4,4,6,6-pentamethylcyclotrisiloxane ([OSiMe₂]₂[OSiMe(NMe₂)]); 2-dimethylamino-2,4,4,6,6,8,8-heptamethylcyclotetrasiloxane ([OSiMe₂]₃[OSiMe(NMe₂)]); and the like.

### Amino Siloxane and Derivatives Thereof

A silicon-containing precursor can include siloxane or a derivative thereof and having one or more amino substitutions, thereby providing a siloxane or a derivative thereof having one or more Si—O, O—Si—O, or Si—O—Si bonds and having one or more-NR² substitutions. In one embodiment, the precursor has a formula of (R″)_{3-y}N[SiR′₂—(OSiR′₂)_{z}—R′]_{y}, wherein:
y is 1, 2, or 3;
z is 1, 2, 3, or more;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″)_{3-y}N[(SiR′₂—O)_{z}—SiR′₃]_{y}, wherein R′, R″, y, and z can be any described herein.

The precursor can include an optionally substituted amino group with an optionally substituted silyl group. In one embodiment, the precursor has a formula of R″₂N—SiR′₂—(OSiR′₂)_{z}—R′ or R″₂N—SiR′₂—O—SiR′₃, wherein R′, R″, and z can be any described herein. In another embodiment, the precursor has a formula of R″₂N(SiR′₂—O)_{z}—SiR′₃, wherein R′, R″, and z can be any described herein.

The precursor can include two optionally substituted amino group. In one embodiment, the precursor has a formula of R″₂N—SiR′₂—(OSiR′₂)_{z}—NR″₂, wherein R′, R″, and z can be any described herein.

In some embodiments, R′ is H, optionally substituted aliphatic, optionally substituted alkyl, optionally substituted alkenyl, or optionally substituted alkynyl. In other embodiments, R″ is H, optionally substituted aliphatic, optionally substituted alkyl, optionally substituted alkenyl, or optionally substituted alkynyl. In particular embodiments, z is 1, 2, or 3.

Non-limiting precursors can include, e.g., 1-dimethylamino-pentamethyldisiloxane (Me₂N—SiMe₂-OSiMe₃); 1-diethylamino-pentamethyldisiloxane (Et₂N—SiMe₂-OSiMe₃); 1-ethylmethylamino-pentamethyldisiloxane (EtMeN-SiMe₂-OSiMe₃); 1,3-bis(dimethylamino) tetramethyldisiloxane (Me₂N—SiMe₂-OSiMe₂-NMe₂); 1-dimethylamino-heptamethyltrisiloxane (Me₂N—SiMe₂-[OSiMe₂]₂-Me); 1,5-bis(dimethylamino) hexamethyltrisiloxane (Me₂N—SiMe₂-[OSiMe₂]₂—NMe₂); and the like.

### Silanols, Including Alkyl Silanols or Alkoxy Silanols

A silicon-containing precursor can include one or more hydroxyl groups, thereby providing a non-limiting silanol. In one embodiment, the precursor has a formula of (R′)₄₋ₓSi(OH)ₓ, wherein:
x is 1, 2, 3, or 4; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In other embodiments, the precursor has a formula of (R′)_{z}Si(OH)ₓ(OR″)_{y}, wherein:
x is 1, 2, 3, or 4;
each of y and z is, independently, 0, 1, 2, or 3;

$$x + y + z = 4 ;$$

each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, silyl, or silyloxy, in which any of these may be optionally substituted.

The precursor can have one hydroxyl group. In one embodiment, the precursor has a formula of (R′)₃Si(OH), in which each R′ can be any described herein. In another embodiment, the precursor has a formula of Si(OH)(OR″)₃, in which each R″ can be any described herein. In particular embodiments, R″ is optionally substituted alkyl (e.g., Me, Et, nPr, iPr, sBu, or tBu), in which the optionally substituted alkyl is linear, branched, substituted, or unsubstituted.

Non-limiting precursors include, e.g., tri (t-butoxy) silanol (SiOH[OtBu]₃); tri (t-pentoxy) silanol (SiOH[OtPe]₃); and the like.

### Carbonyloxy Silanes

A silicon-containing precursor can include one or more optionally substituted aliphatic-carbonyloxy groups, thereby providing a non-limiting carbonyloxy silane. In one embodiment, the precursor has a formula of (R′)₄₋ₓSi(OC(O)—R″)ₓ, wherein:
x is 1, 2, 3, or 4;
each R′ is, independently, H, aliphatic, aliphatic-carbonyl, aliphatic-oxy, aliphatic-oxycarbonyl, heteroaliphatic, heteroaliphatic-carbonyl, heteroaliphatic-oxy, heteroaliphatic-oxycarbonyl, aromatic, aromatic-carbonyl, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, or aminooxy, in which any of these may be optionally substituted.

In another embodiment, the precursor has a formula of (R″—C(O)O)ₓ(R′)₃₋ₓSi-L-Si(R′)₃₋ₓ(OC(O)—R″)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-oxy, aliphatic-oxycarbonyl, heteroaliphatic, heteroaliphatic-carbonyl, heteroaliphatic-oxy, heteroaliphatic-oxycarbonyl, aromatic, aromatic-carbonyl, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, or aminooxy, in which any of these may be optionally substituted.

In some embodiments, R′ is H, optionally substituted amino (e.g., —NR²), aliphatic-oxy (e.g., alkoxy or —OR), aliphatic-carbonyl (e.g., alkanoyl or —C(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In some embodiments, R″″ is H, optionally substituted alkyl, optionally substituted alkenyl, optionally substituted alkynyl, optionally substituted alkoxy, optionally substituted aryloxy, optionally substituted amino, or optionally substituted aminooxy.

Non-limiting precursors include those having a formula of (R′)₂Si(OC(O)—R″″)₂, wherein R′ and R″″ can be any described herein.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for processing substrates, the method comprising:
providing a substrate having a feature having a feature opening to a process chamber;
conformally depositing a first portion of a material into the feature;
stopping depositing into the feature before a seam forms in the feature;
after partially depositing the first portion of the material, exposing the substrate to an etching species to etch an angular opening at or near the feature opening to form an etched surface; and
depositing a second portion of the material onto the etched surface to fill the feature.

2. The method of claim 1, wherein at least one of the first portion and the second portion of the material is deposited using plasma-enhanced atomic layer deposition.

3. The method of claim 1, wherein the second portion of the material is deposited using plasma-enhanced chemical vapor deposition.

4. The method of claim 1, wherein the second portion of the material is deposited using thermal chemical vapor deposition and a post-treatment process.

5. The method of claim 1, wherein the process chamber is a single-wafer process chamber.

6. The method of claim 1, wherein the conformally depositing of the first portion and the exposing the substrate to the etching species is performed without breaking vacuum.

7. The method of claim 1, wherein the etching species is oxygen-free.

8. The method of claim 1, wherein the angular opening is etched to a depth of less than about 10% of the depth of the feature.

9. The method of claim 4, wherein the post-treatment is performed in an environment oxygen-free environment and/or the post-treatment comprises exposing the substrate to a plasma.

10. An apparatus for processing substrates, the apparatus comprising:
one or more process chambers, each process chamber comprising a chuck;
one or more gas inlets into the process chambers and associated flow-control hardware; and
a controller having at least one processor and a memory, wherein
the at least one processor and the memory are communicatively connected with one another,
the at least one processor is at least operatively connected with the flow-control hardware, and
the memory stores computer-executable instructions for controlling the at least one processor to at least control the flow-control hardware to:
cause introduction of a first deposition precursor and a first reactant in temporally separated pulses to partially fill a feature on a substrate with a first portion of material;
cause introduction of an etching gas to etch the first portion of the material to form an angular opening at or near a feature opening of the feature; and
cause introduction of a second deposition precursor and a second reactant and optional generation of a plasma to form a second portion of the material to fill the feature.
